(19) United States
(12) Patent Application Publication
(10) Pub. No.: US 2009/0039407 A1
(43) Pub. Date: Feb. 12, 2009

(54) Vertically integrated flash EPROM for greater density and lower cost

(76) Inventor: Madhukar B. Vora, Los Gatos, CA (US)

Correspondence Address: RONALD CRAIG FISH, A LAW CORPORATION, PO BOX 820, LOS GATOS, CA, 95032, US

(21) Appl. No.: 12/150,079

(22) Filed: Apr. 24, 2008

Related U.S. Application Data
(62) Division of application No. 11/083,683, filed on Mar. 17, 2005.

(51) Int. Cl. H01L 29/78; H01L 21/336

(52) U.S. Cl. 257/316; 438/257; 257/E29.255

(57) ABSTRACT

A nonvolative memory in the form of a vertical flash EPROM with high density and low cost. A vertical MOS transistor is formed in well etched into a semiconductor substrate, the substrate having source, body and drain regions formed by ion implantation. A thin gate oxide or oxide-nitride-oxide (ONO) layer is formed in the well and a self-aligned floating gate of polysilicon is formed over the gate oxide in the well to overlie the body region. An anisotropic etch is used to form the self aligned floating gate so as to remove all horizontal components and leave no portion of said floating gate extending beyond the perimeter of said well such that its lateral extents are determined by the anisotropic etch and not photolithography. L_{eff} is determined by the energy of the implants used for form the source and drain regions and not by lithography. A deep field oxide bounding parts of said well keeps the coupling ratio good at all feature sizes. A vertically oriented NMOS and PMOS transistor are also disclosed.

### BACKGROUND OF THE INVENTION

The invention pertains generally to the field of semiconductor, nonvolatile memories, and, more particularly, to the field of vertically-integrated, flash EPROMS which can be manufactured with sufficient density to be cheap enough to compete with rotating magnetic media for bulk memory applications. The vertically-integrated, flash EPROM according to the teachings of the invention is especially useful in personal computers of the laptop, notebook and palmtop variety although it is broadly applicable to any application where large, nonvolatile memory is needed which is physically rugged and competitive with disk drives in price.

Flash EPROMS are known in the prior art, but the problem to date has been that they cannot be made cheaply enough for them to have mass market appeal. The size of prior art EPROM cells has been so large, that the number of cells per semiconductor die that can be made with adequate yield was too low to have a cost which was competitive with rotating memories such as disk drives.

Prior art flash EPROM cells of the most aggressive design made by Intel Corporation of Santa Clara, Calif. are 7-8 square microns using 0.8 micron design rules. With a semiconductor die size of 1 square centimeter, this cell size allows flash EPROMS of 4-8 megabits to be built for a cost of about $30 per megabit.

In contrast, small disk drives can be manufactured for about $5 per megabyte. Therefore, a need has arisen for a smaller flash EPROM cell such that more dense memories can be built for lower cost.

### SUMMARY OF THE INVENTION

According to the teachings of the invention, a vertically constructed flash EPROM cell is taught herein which allows a very small cell size to be achieved. The vertically oriented flash EPROM consists of a recess in a semiconductor substrate that extends down through drain, body and source regions of the substrate. The source and drain regions are formed by ion implants into a substrate doped to have the desired conductivity of the body of the vertically oriented EPROM transistor where the channel region will be formed under proper voltage conditions. In the preferred embodiment, the source, body and drain regions are doped N, P and N type respectively, but in alternative embodiments, the source, body and drain could be doped P, N and P type.

An annular self-aligned floating gate is formed over thin gate oxide which is formed on the recess walls. Self-aligned as that term is used herein means the lateral extents of the floating gate beyond the recess walls are not determined by photolithography. Instead, the lateral extents of the floating gates are determined by the inherent characteristic of the anisotropic etch which is used to form the floating gates of all active EPROM cells. What this means is that an anisotropic etch is used to form the floating gates, and this etch removes all horizontal components of the floating gate material and leaves only floating gate material on the vertical walls of the EPROM cells. Therefore, there is no floating gate material that extends up out of the recess and horizontally across the surface of the substrate. This, plus the fact that the EPROM transistor (and the vertical n-MOS transistors also disclosed herein) is vertically oriented explains why the horizontal cell area of each EPROM cell and vertically oriented n-MOS transistor can be made so small. That is, the length of the transistor is vertical and not horizontal across the surface of the die substrate. Also, lithography is not used to determine the final configuration of the floating gate, so there are no misalignment error design rule tolerances that must be taken into account when making the floating gates. Having to leave room for misalignment errors in making floating gate structures in horizontally oriented EPROMs makes horizontally oriented EPROM cells larger than they need to be.

Another major advantage of a vertically oriented EPROM cell or vertically oriented n-MOS transistor is that the gate length L_{eff} is controlled by the energy of the ion implants used to form the source and drain regions and not by photolithograpy. As a result, very precise gate lengths can be obtained and the variations between lots during manufacture is much less than in horizontally oriented EPROM cells where the gate length is determined by photolithography. As feature sizes get smaller, it becomes much more difficult to precisely control gate lengths with photolithography and plus or minus 25% of the desired gate length is typical in photolithographic processes to make horizontal EPROMs.

The floating gate has charge stored on it under certain conditions of programming to raise or lower the threshold of the transistor such that when a voltage differential is applied between the control gate and source, a channel region either will or will not be formed through body layer of the substrate between the source and drain regions thereby causing conduction between the source and drain or no conduction depending upon the state of charge of the floating gate. The state of charge on the floating gate determines whether the cell stores a logic one or zero.

Another major advantage of a vertically oriented EPROM cell is that the floating gate length can be made longer without a density penalty in terms of how many EPROM cells can be fit on one die. This is because the floating gate extends vertically. The interval an EPROM cell floating gate is capable of holding its charge without refresh is a function of its volume. In horizontally oriented EPROM cells, the volume of the floating gate gets smaller as feature sizes get smaller because the floating gate extends horizontally in two directions in prior art EPROM cells. In the vertically oriented EPROM cell taught herein, the volume of the floating gate is determined by its vertical length and its thickness and the perimeter of the recess in which it is formed. This volume can be made much greater than in horizontally oriented EPROM cells without significant density penalty.

The control gate is formed to extend down into the recess and overlie the floating gate. An extension of the control gate forms the word line which is in electrical contact with the control gate of every cell in a row of the array. In some embodiments, a third layer of polysilicon overlying the word line but insulated therefrom is formed so as to make contact with the drain layer in the substrate at each cell location to form a bit line for each column of cells in an array of cells. In some embodiments, a buried N layer (or P layer depending upon whether the basic transistor is NMOS or PMOS) acts as a source and a first bit line which contacts the source region of every cell in the row, and a second conductive layer contacting the drain region of every cell in the row acts as a second bit line.

The self alignment of the floating gate causes large savings in cell area thereby making each cell much smaller because of the elimination of tolerances which would be required by the design rules if the floating gates were to be formed using masks and photolithography. This is true in all embodiments disclosed herein except the vertical NMOS transistor which does not have a floating gate because it is not a non volatile memory cell.

The original vertical flash EPROM embodiment is disclosed in FIGS. 1-34. The first alternative embodiment (FIGS. 38, 39 and 40) greatly improves the coupling ratio by decreasing the C1 capacitance by forming the field oxide on a portion of the perimeter of the recess much deeper. The coupling ratio is defined by the equation C2/(C2+C1) where C2 is the capacitance between control gate poly (110 in FIG. 39) and floating gate poly (102 in FIG. 39) separated by ONO (Oxide/Nitride/Oxide) (104 in FIG. 39). C1 is the capacitance between floating gate and the P substrate (82 in FIG. 39) separated by thin gate oxide (100 in FIG. 39). The second embodiment shown in FIGS. 52A through 52C has the same coupling ratio improvement as the first alternative embodiment, but it is easier to manufacture because its process sequence is simpler. The third alternative embodiment is disclosed in FIGS. 54A through 54C. The main advantage of this embodiment is that it the cell area goes down 4F squared (the cell area of the embodiment of FIGS. 1-34) to 3F squared where F is the minimum feature size. This embodiment also has the improved coupling ratio advantage of all the alternative embodiments, and this improved coupling ratio will stay above 50% even as the cell size is scaled down to 0.13 micron rules and all the way down to 0.065 micron rules and maybe even smaller feature sizes such as 0.003 microns. A fourth alternative embodiment is disclosed in FIGS. 57A through 57C. The main advantage of this embodiment is the cell area is 2F squared and the coupling ratio becomes approximately 50% regardless of feature size because the sizes of the two floating gate halves are equal to the sizes of the control gate so the capacitance C1 approximately equals C2 even as the feature sizes are scaled down.

The last alternative embodiment disclosed herein is a vertical NMOS transistor shown in FIGS. 67A through 67C. This transistor has no floating gate and acts like a conventional NMOS transistor but is much smaller because of its vertical orientation. The cell size for one transistor is half the size of a normal NMOS transistor that is laid out in the horizontal plane, and this is true as the feature sizes are scaled down. Another major advantage of the vertical NMOS transistor is that the L_{eff} is independent of lithography which is not true in a horizontally oriented conventional NMOS transistor. As those skilled in the art understand, L_{eff} is the distance between the source and drain. This distance affects the drain current, and the value of fₜ which affects the speed of switching of the transistor. Because in the vertically oriented NMOS transistor control of L_{eff} and fₜ is so much better (plus or minus 1-5%) than in conventional horizontal NMOS transistors (typically plus or minus 25% for 0.9 micron feature sizes and below), the yields are better in the vertically oriented NMOS transistors.

With present 6 inch wafers and 0.8 micron design rules and 40,000-60,000 square mil dies, the cost per megabit of memory cells is a substantial improvement over the $30 per megabit cost of prior art EPROM cells. With the migration toward 8 inch wafers and 0.6 micron design rules larger die sizes of 100,000-200,000 square mils will be possible, and the cost per megabit of memory cells according to the teachings of the invention should improve greatly. With 2005 design rules at 0.13 microns, it should be possible to build 1 GB flash EPROMs on a die of one square centimeter with a cost of about $10 per gigabit. This is an approximate factor of three improvement over the area of the current state of the art flash EPROM cell in NOR type configuration. An alternative embodiment disclosed herein in FIGS. 57 through 66 with a split floating gate will provide a factor of six improvement over the area of the current state of the art flash EPROM cell in NOR configuration.

### BRIEF DESCRIPTION OF THE DRAWINGS

FIG. 1 is a cross-sectional view of a semiconductor substrate at an intermediate stage in construction of a vertical EPROM cell after the recessed gate window has been formed and first polysilicon has been deposited.

FIG. 2 is a cross-sectional view of a semiconductor substrate at an intermediate stage in construction of a vertical EPROM cell after the floating gate has been formed.

FIG. 3 is an equivalent circuit showing the two capacitors of the floating gate structure.

FIG. 4 is a vertical cross-sectional diagram of a typical prior art EPROM cell through the floating gate structure.

FIG. 5 is a vertical cross-sectional diagram of the finished vertical EPROM structure.

FIG. 6 is a plan view of a cell array using the vertically oriented EPROM cells according to the invention.

FIGS. 7A, B and C through FIGS. 31A, B and C are cross-sectional views showing various stages of simultaneous construction of an NMOS transistor, a PMOS transistor and a vertically oriented EPROM cell according to a process compatible with fabrication of CMOS drivers for the EPROM array according to the teachings of the invention.

FIG. 32 is a plan view of four cells in an array of EPROM cells according to the teachings of the invention.

FIG. 33 is a sectional view through a typical EPROM cell according to the teachings of the invention taken along section line A-A′ in FIG. 32.

FIG. 34 is a sectional view through a typical EPROM cell according to the teachings of the invention taken along section line B-B′ in FIG. 32.

FIG. 35 is a top view of a state of the art conventional, horizontally oriented prior art NMOS transistor.

FIG. 36 is a section view along section line AA′ in FIG. 35.

FIG. 37 is a section view along section line BB′ in FIG. 35.

FIG. 38 is a top view of the original embodiment of a vertical flash EPROM cell disclosed in FIG. 5.

FIG. 39 is a sectional view along line AA′ of FIG. 38.

FIG. 40 is a sectional view along line BB′ of FIG. 38.

FIG. 41 is a three view of the floating gate/poly/ONO sandwich tube in the original embodiment of FIG. 38.

FIGS. 42A through 42D are various views of the first alternative embodiment of the vertical flash EPROM.

FIGS. 43A-43C are various views of an array of cells of the embodiment of FIGS. 42A-42D including a schematic of the equivalent circuit of the array and a table describing the operation of the array.

FIG. 44 is an equivalent circuit of the array of FIG. 43A.

FIG. 45 is a table of operation showing the voltage conditions needed to program, read and erase an EPROM cell such as is shown in FIGS. 43A-43C.

FIGS. 46A through 51C are drawings of various steps in the process to form the deeper field oxide in the first, second and third alternative embodiments.

FIGS. 52A-52D are various views of the second alternative embodiment of the vertical flash EPROM.

FIGS. 53A-53E are various views of an array of cells of the embodiment of FIGS. 52A-52D including a schematic of the equivalent circuit of the array and a table describing the operation of the array.

FIGS. 54A-54D are various views of the second alternative embodiment of the vertical flash EPROM.

FIGS. 55A-55E are various views of an array of cells of the embodiment of FIGS. 54A-54D including a schematic of the equivalent circuit of the array and a table describing the operation of the array and how to address transistor T3.

FIGS. 56A-56E are various views of an array of cells of the embodiment of FIGS. 54A-54D including a schematic of the equivalent circuit of the array and a table describing the operation of the array and how to address transistor T6.

FIGS. 57A-57D are various views of the third alternative embodiment of the vertical flash EPROM.

FIGS. 58A-65C are diagrams showing sections and top views at various steps of the process to build the embodiment of FIG. 57A-57D (a different process to create the same vertical flash EPROM structure but which enables twice the density of the first alternative embodiment while retaining the improved coupling ratio).

FIGS. 66A-66E show the completed structure of an array of vertically oriented EPROM cells having the structure built using the process of FIGS. 58A-65C and an equivalent circuit for the array of FIG. 66A and a table of operation showing voltage conditions to program, read and erase the cells.

FIGS. 67A-67D are various views and an equivalent circuit of a vertically oriented NMOS transistor cell having two NMOS transistors in each recess.

FIG. 68A is an enlarged view of the channel region shown in FIG. 67B.

FIG. 68B is a schematic of the intrinsic transistor of the type shown in FIG. 67A-67D.

FIG. 69A is a top view of a conventional horizontal NMOS prior art transistor.

FIG. 69B is a top view of the vertical NMOS transistor of the invention illustrating the improvement in cell area for the same width over length ratio.

### DETAILED DESCRIPTION OF THE PREFERRED EMBODIMENT AND ALTERNATIVE EMBODIMENTS

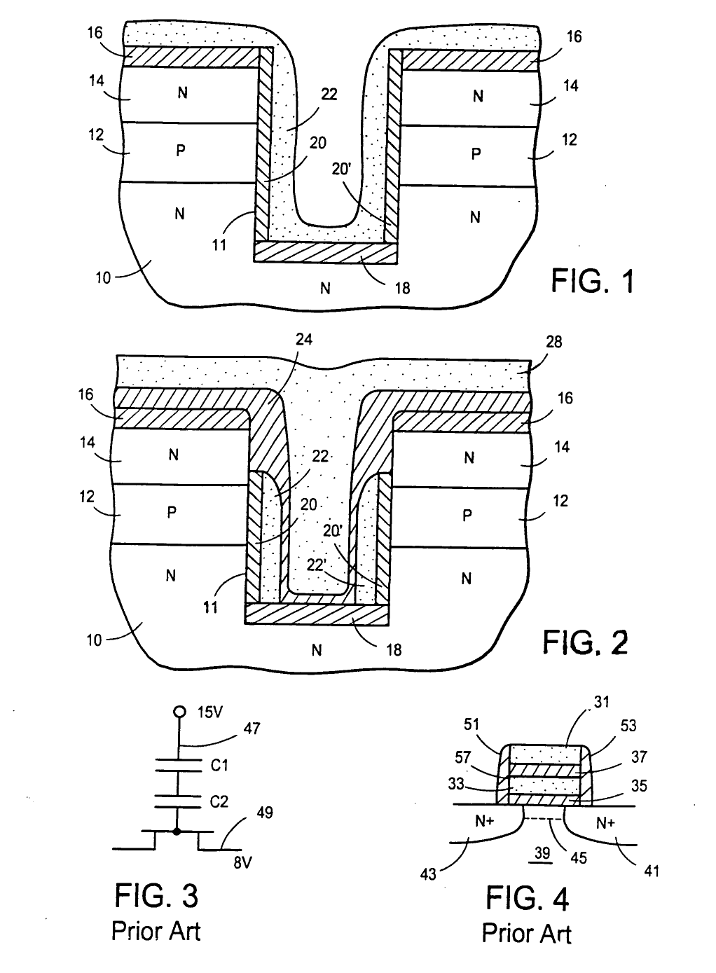

Referring to FIG. 1, there is shown a cross-sectional view of an intermediate stage in the construction of the EPROM memory cell according to the teachings of the invention. Although a detailed process schedule and series of drawings illustrating the exact method of making one embodiment of the invention will be presented below, FIGS. 1-3 will be used to summarize the construction of an EPROM memory cell according to the teachings of the invention.

To reach the stage of construction shown in FIG. 1, a one micron deep well is etched into an N type silicon substrate 10 having a resistivity of ______. A P doped region 12 is formed about midway down the well. An N doped region 14 lies above the P type region 12. An oxide layer 16 having a thickness of about 2000 angstroms is grown on top of the substrate. An oxide layer 18 is grown at the bottom of the well and has a thickness of about 1000 angstroms. A thin annular oxide layer, sections of which are shown at 20 and 20′, is grown on the sidewalls of the well to insulate a first layer of doped polysilicon 22 which is deposited on the surface of the substrate and into the well.

FIG. 2 shows a subsequent stage of construction after an anisotropic etchback to remove the upper portions of the first polysilicon layer and the first polysilicon lying in the bottom of the well above oxide layer 18. This leaves a floating gate comprised of an annular first polysilicon layer, two sections of which are shown at 22 and 22′. This floating gate is isolated from the substrate by the thin oxide layer 20. To complete the electrical isolation of the floating gate layer 22, a layer of ONO insulator 24 is deposited over the surface of the substrate and in the well.

The thickness and integrity of the ONO layer is important to the coupling ratio in an EPROM which is important in the write process. Referring to FIG. 3, there is shown an equivalent circuit of the floating gate and control gate structure shown in FIG. 4. Although FIG. 4 represents the structure of a typical prior art floating gate EPROM structure, it is used here to illustrate the functioning of an EPROM cell and the significance to the write process of the coupling ratio between the capacitance of capacitor C2 and the capacitor C1 in FIG. 3. Capacitor C2 represents the capacitor formed between the control gate 31 and the floating gate 33 in FIG. 4. Capacitor C1 represents the capacitor formed between the floating gate 33 and the substrate 39. Layers 35 and 37 are thin oxide or ONO insulating layers (oxide-nitride-oxide) that separate the polysilicon one floating gate layer 33 from the substrate 39, and the polysilicon one floating gate layer from the polysilicon two control gate layer 31, respectively. These two insulation layers separating the conductive polysilicon layers define the capacitors C1 and C2 in FIG. 3. Two oxide spacer layers 51 and 53 insulate the self aligned edges of the stacked control gate and floating gate structure.

One problem with the prior art stacked structure of FIG. 4 was leakage at the corner 57 where ONO is used for insulation layer 37. At this corner, ONO joins the oxide of the spacer layer 51 (the same holds true for the other side) and the electrical seal against charge leaking out of the floating gate is not perfect because of the concentration of electric field lines at this corner.

The significance of the coupling ratio pertains to the effectiveness of causing injection of electrons or wells into the floating gate 33 so as to alter the trapped charge therein. It is the presence of trapped charge in the floating gate 33 which alters the threshold of the MOS transistor formed by the floating gate 33, and the source region 41 and the drain region 43 in FIG. 4. For one state of trapped charge, an inversion of conductivity type in the substrate 39 between the source and drain regions will occur thereby forming a conductive channel through which conduction occurs between the source and drain regions. This channel is symbolized by is dashed line 45, and this state of charge can be defined as either a binary 1 or 0. In the other state of charge of the floating gate, no inversion channel occurs, and no conduction between the source and drain occurs. Charge is trapped in the floating gate 33 by tunneling or injection during the write or program process. It is desirable to have the capacitance of capacitor C1 much less than the capacitance of capacitor C2 to insure that sufficient injection or tunneling of electrons from the source or channel region into the floating gate occurs during the write process. This injection or tunneling phenomenon occurs when approximately 15 volts is applied to the control gate terminal 47 in FIG. 3 and approximately 8 volts is applied to the source 49 during the write process if C2 is greater than C1. C2 and C1 effectively form a voltage divider between the potential applied to the control gate terminal 47 and the potential of the channel region. It is desirable to have relatively more of the voltage drop from the channel to the control gate terminal 47 occur across capacitor C1 to maximize the tunneling phenomenon. In other words, when the programming voltage is applied, tunneling current begins to charge up both capacitors. The smaller capacitor C1 charges up to a higher voltage thereby altering the threshold of the MOS transistor sufficiently to create the inversion channel.

Therefore, since the first oxide layer 35 in FIG. 4 or 20 in FIG. 2 should be very thin to increase the capacitance of C1 to enhance tunneling current for writing and erasing, it is necessary for the second oxide layer 37 to be as thin or thinner than the first oxide layer so that C2 is greater than C1. Alternatively, the area of C2 can be made greater than the area of C1. Because of the need for a thin second insulator layer, the material used for the second insulating layer 37 is very important in that it must have high electrical integrity. Generally, ONO is preferred for this purpose because of its high integrity as an electrical insulator and oxide interfaces on both surfaces. Because ONO creates more surface states which would adversely affect the operation of the underlying MOS transistor, ONO cannot be used for the first insulation layer 20 in FIG. 2.

ONO layer 24 in FIG. 2 is made by oxidizing the underlying layers to a thickness of about 30 angstroms and then depositing approximately 150 angstroms of nitride. Thereafter, steam oxidation of the nitride is performed to form an additional 30 angstroms of oxide. Because of the different dielectric constant of nitride, the overall dielectric constant of the ONO layer 24 is approximately the same as that of 100 angstroms of oxide. ONO works especially well to preserve the trapped charge in the floating gate to alleviate a problem of escaping charge at the corners of the floating gate which existed in the prior art.

After the ONO layer 24 is deposited, a second layer of doped polysilicon 28 is deposited to fill the well and is etched to form the word line.

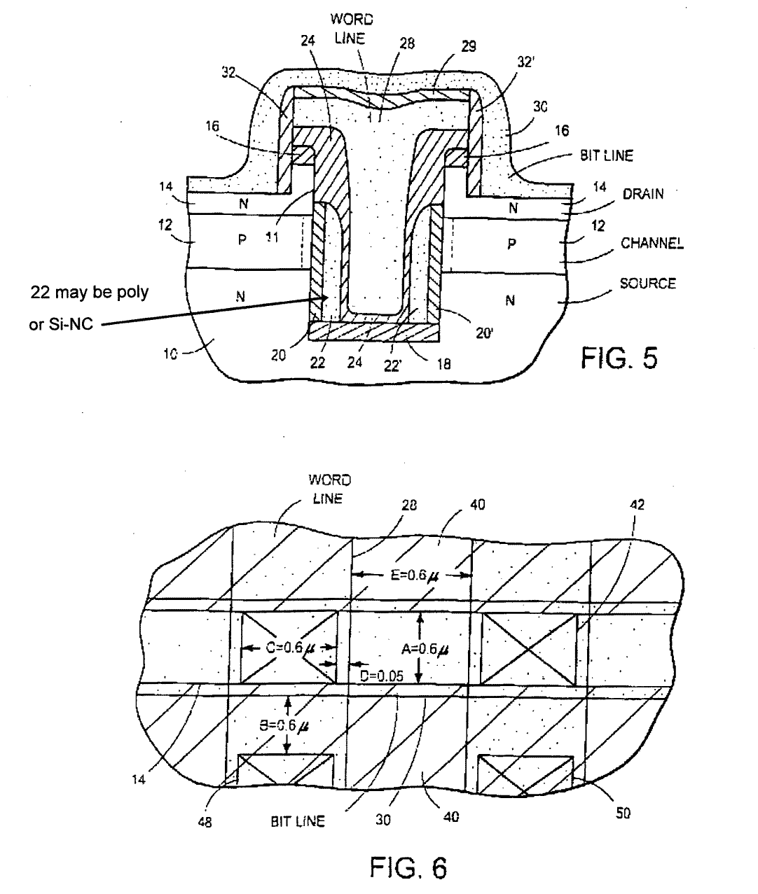

FIG. 5 shows in vertical section the completed device. To reach the state of construction shown in FIG. 5, a layer of oxide 29 is grown on the second polysilicon layer 28. Then a mask is formed over the second polysilicon layer 28 to protect the portion thereof overlying the well which it fills. Thereafter, an anisotropic etch is performed to etch down through the polysilicon layer 28, the ONO layer 24, the oxide layer 16 and part of the way through the N-type silicon layer 14 to open a contact well for the bit line 30.

After this contact well is opened, an annular oxide spacer, sections of which are shown at 32 and 32′, is formed to seal and insulate the sides of the structure from the bit line to be formed next. The oxide spacer is formed by growing or depositing a layer of oxide over the entire structure and anisotropically etching it back to leave the vertical sections of oxide.

The bit line is shared by all devices in a row and is formed by depositing a third layer of polysilicon 30 over the entire structure and etching it to selectively make contact with the N-type silicon layer 14 which forms the drain of the vertical annulus MOS transistor formed inside the well. The source of the vertical MOS transistor is the N-type substrate 10. The channel region for this transistor is formed by the P-type silicon layer 12. The gate oxide between the channel region and the floating gate 22 is oxide layer 20. The control gate is comprised of second polysilicon layer 28, and extends down into the page and up out of the page to form the word line.

FIG. 6 shows a plan view of the EPROM cell. Field oxide 40 defines the outer boundaries of the N-type silicon layer 14 through which the wells 13 and 42 are formed. The polysilicon or metal bit line 30 (polysilicon is shown and preferred for better step coverage) runs from left to right over and in contact with the N-type silicon layer 14 and slightly overlaps the field oxide layer. The bit line also overlaps the word line polysilicon 28 which fills the well 11. The details of the structure down inside the well are not shown in FIG. 6 for simplicity.

The length of the cell shown in FIG. 6 is equal to the dimension A defining the length of the well plus the dimension B which defines the pitch or minimum spacing between the wells. In FIG. 6, the next row of wells is represented by wells 48 and 50. For 0.6 micron design rules, A=0.6 micron and B=0.6 microns for a total length of 1.2 microns.

The width of the cell is equal to the dimension C which defines the width of the well, plus the dimension D which defines the overlap of the second polysilicon layer 28 past the edge of the well, plus the dimension E equal to the pitch between the second polysilicon word lines 28 between columns. For 0.6 micron design rules, C=0.6 microns, D=0.05 microns and E=0.6 microns for a total cell width of 1.3 microns. Thus, the total cell area for 0.6 micron design rules is 1.56 square microns.

With a cell size of 1.56 square microns, a 64 megabit EPROM memory can be built on a die of 1-2 square centimeter size. With 6 inch wafers, the wafer area is 28 square inches. At 6.54 square centimeters per square inch, a 6 inch wafer contains 182 square centimeters. With a die size of 2 square centimeters, a 6 inch wafer yields about 90 die. Because well known redundancy techniques can be used to repair defective cells, yields in EPROM production are typically high, averaging around 80 percent. Thus, a typical production run will yield about 72 good die. Typical production costs for a 6 inch wafer are about $500, so the cost per 64 megabit (8 megabytes) die is about $6.94 or about $0.86 per megabyte. A 40 megabyte EPROM memory using the teachings of the invention would cost about $34.72. This cost should come down with the introduction of 8 inch wafers at 0.6 micron line widths. Typical costs are expected to be about $3.87 per 8 megabyte EPROM memory or 48 cents per megabyte for a total cost for a 40 megabyte memory of $19.37. Of course any change in any of the numbers of assumptions or numbers used in the above calculations will yield different costs per megabyte. Todays cost for typical prior art EPROM memory sold by Intel Corporation is about $30 per megabyte manufactured using 0.8 micron design rules. Note that in the above cost calculations, 0.6 micron linewidths were assumed. Costs for prior art EPROM cells using 0.6 micron design rules should fall to about $15 per megabyte.

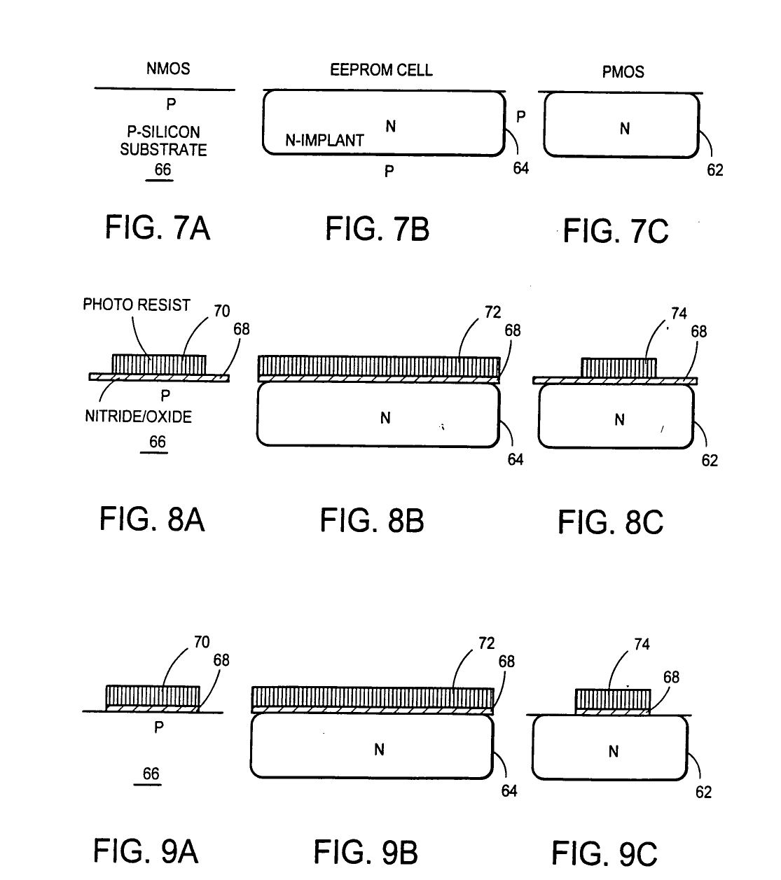

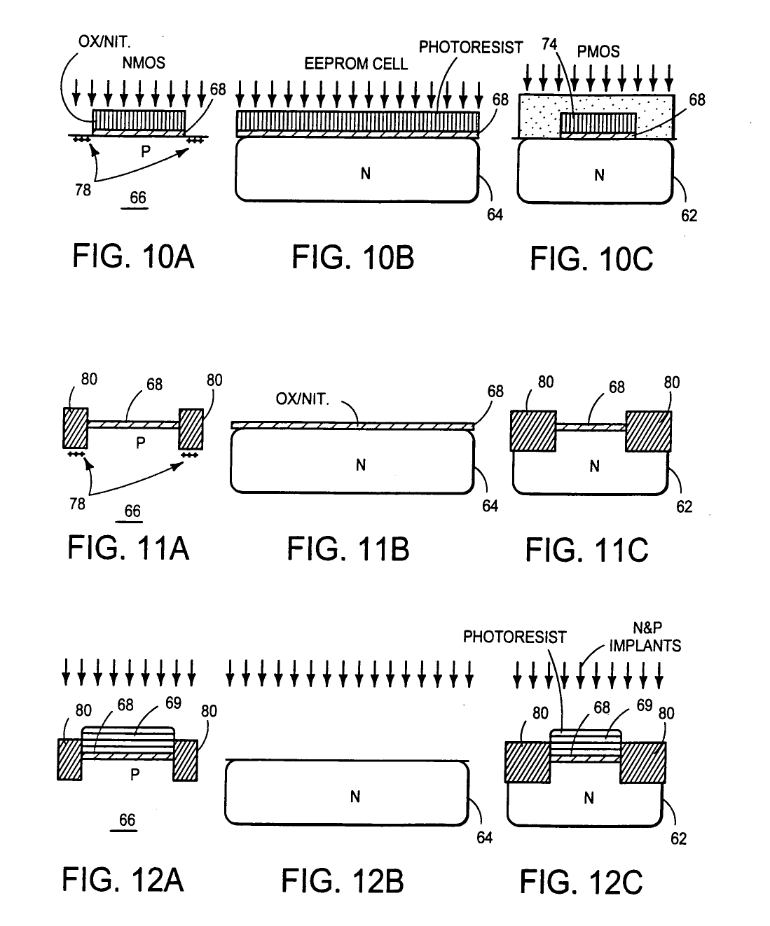

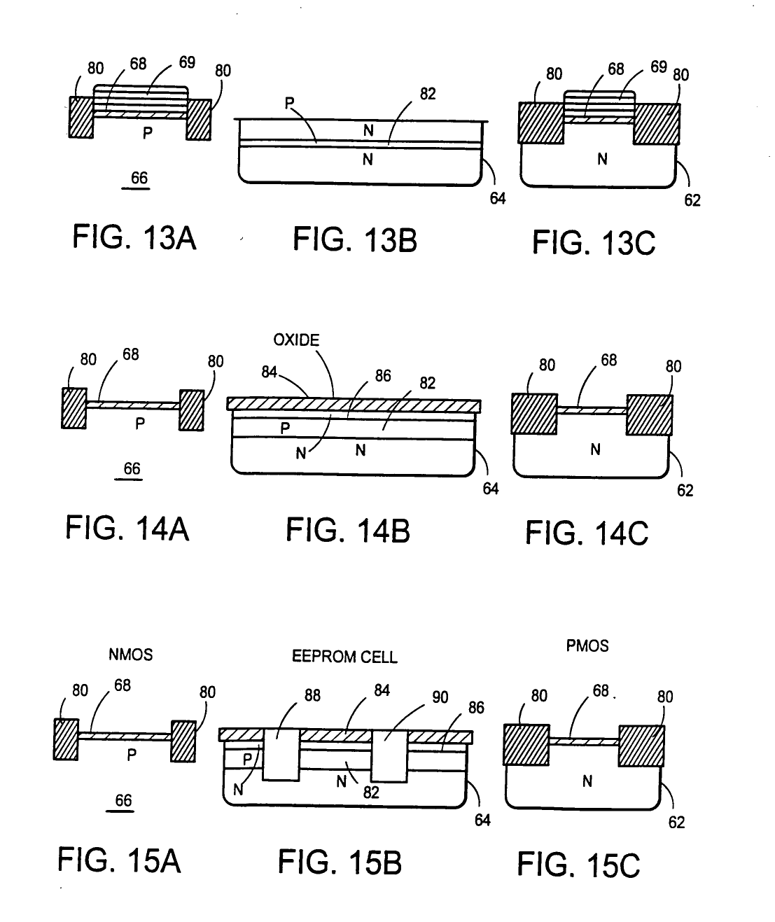

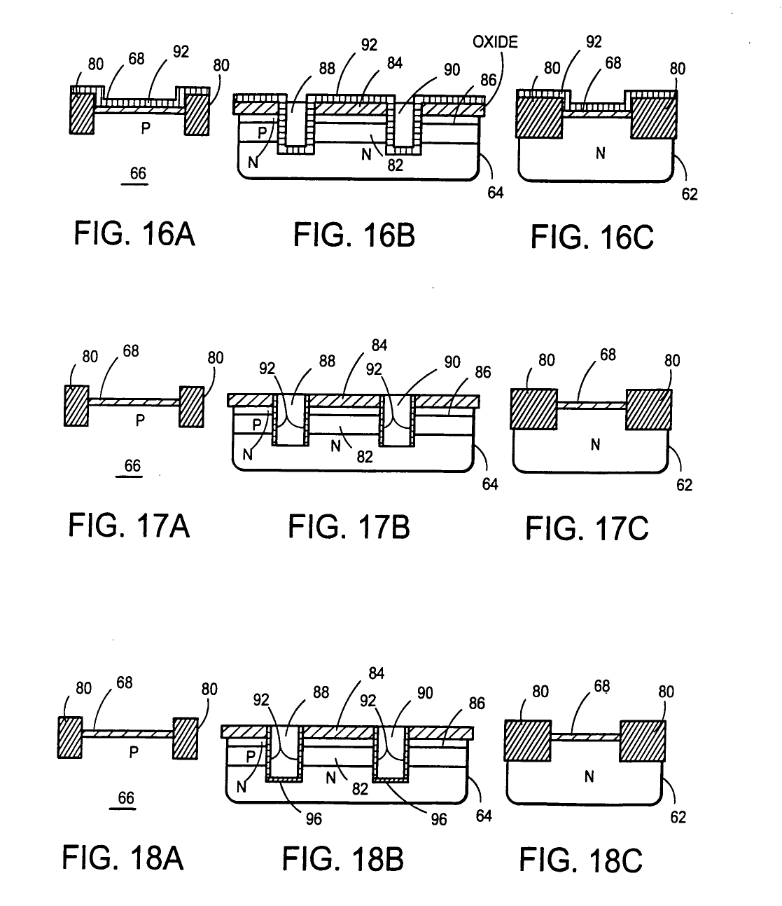

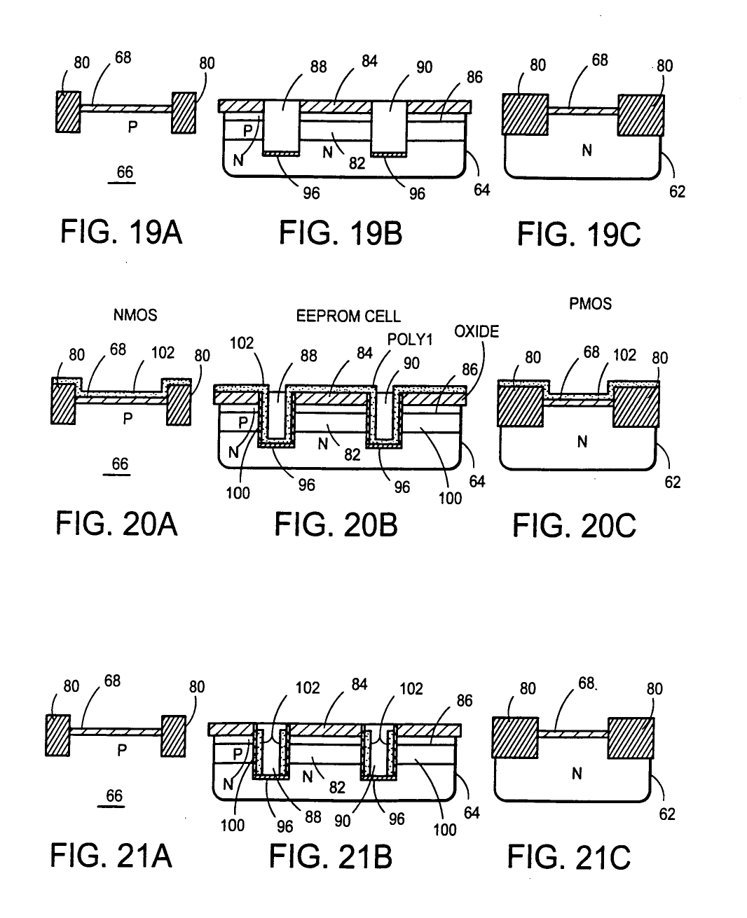

A detailed description of how to make the EPROM memory cell according to the teachings of the invention follows in connection with the discussion of FIGS. 7A, B and C through FIGS. 30A, B and C. The preferred process is compatible with CMOS processing so that the EPROM memory can be built on the same die with CMOS drivers. Accordingly, in each of FIGS. 7A, B and C through FIGS. 30A, B and C, the figure in the left column labelled Figure A is the corresponding NMOS structure and the figure in the right column labelled Figure C is the corresponding PMOS structure. A summary of the process is given in Appendix A. In Appendix A, the individual steps in the process are numbered, and the steps in which the masks are used are given in the column second from the right. The figure numbers in the rightmost column of Appendix A show the state of construction after the steps preceding the line on which the particular figure number is listed have been completed.

Referring to FIGS. 7A, B and C, there is shown the state of construction after the first nine steps in Appendix A. To reach the state of construction shown in FIGS. 7A, B and C, a P-type silicon substrate having a conventional resistivity is used as the starting material.

Then a layer of oxide (silicon dioxide) is thermally grown to a thickness of approximately 300 angstroms.

Next a layer of nitride (silicon nitride) is deposited to a thickness of about 1000 angstroms using chemical vapor deposition (CVD), low pressure CVD (LPCVD) or plasma enhanced chemical vapor deposition (PECVD).

A layer of photoresist is then deposited and developed using the first level twin-well mask to define the twin wells needed to form CMOS devices.

After forming the twin well mask layer of photoresist, the nitride layer is etched away over an area to be implanted with phosphorous to form the N-type wells 62 and 64 in which to form the PMOS device and the EPROM device. Any process for etching the nitride will suffice.

To form the N-well, phosphorous is implanted to a depth of about 3000 angstroms using conventional dosage levels. Then the phoshorous is driven in and the N-well area has another layer of oxide grown thereover using a 1000 degree centigrade oven for one hour. This leaves the structure as shown in FIGS. 7B and 7C with an N-well 62 for the PMOS device, and N-well 64 in which the EPROM device is to be constructed.

Next, the photoresist and nitride are stripped, and boron is implanted to form the P-well 66. Both wells are then driven deeper using a 1100 degree centigrade oven for 5 hours to form wells that are 5-6 microns deep.

The oxide is then etched away over the N-wells 62 and 64 to clear the substrate surface for further processing.

Finally, a 1000 angstrom nitride layer is formed as shown in FIGS. 8A, B and C with the oxide and nitride layers shown as a single layer at 68.

Next, a layer of photoresist is deposited and an active mask (mask 2) is used to cross-link (develop) sections thereof to leave the structure as shown at FIGS. 8A, B and C with a photoresist section 70 over the P-well, photoresist section 72 over the EPROM cell area and photoresist section 74 over the N-well.

The oxide/nitride layer 68 is then etched using the photoresist as a mask to leave the structure as shown in FIGS. 9A, B and C.

A field implant must be performed to implant boron at the edges of the active area of the NMOS device to prevent the formation of parasitic channels, i.e., unintended MOS transistors. To perform this implant, it is necessary to mask off the N well of the PMOS device. This is done by depositing a layer of photoresist 76 and developing it with the field implant mask, i.e., mask 3 to leave the second photoresist layer 76 covering the N well 62. A boron implant is then performed to deposit the P-type field implant impurities shown at 78 in FIG. 10A.

After the field implant, the field regions outside the active areas are oxidized to a thickness of 6000 angstroms to leave the structure as shown in FIGS. 11A, B and C. The field oxide is shown at 80. The areas under the field oxide remain doped so they do not invert and form parasitic MOS devices.

Next the fourth mask is used to remove the nitride portion of layer 68 of oxide/nitride by protecting all structures with photoresist except the oxide/nitride layers 68 over the EPROM cells. After developing the photoresist with the fourth mask, a conventional oxide/nitride etch is performed to leave the structure as shown in FIGS. 12A, B and C with photoresist layer 69 protecting the NMOS and PMOS active areas. This leaves a thin layer of pad oxide (not shown) over the EPROM active areas.

Leaving the photoresist 69 over the NMOS and PMOS wells to protect them, a boron ion implantion is performed through the pad oxide (not shown) to form the buried P region 82 below the surface of the N well in which the EPROM cell is to be formed. Typically, the dosage for this implant will be 1E+12 (on the order of 10 to the 12th power) with an energy level of 100 KEV. This implant forms the channel region in the vertical annular EPROM cell. As the term annular is used herein, the horizontal cross section through the EPROM transistor below the surface of the substrate can be either circular, square, rectangular or some other shape.

Next, leaving the photoresist in place over the NMOS and PMOS devices, an arsenic implant is performed at a lower energy level to redope the area 86 below the surface of the substrate but above the P region 82 back to N type to act as the drain region of the vertical MOS transistor EPROM device, as shown in FIGS. 13A, B and C. Typically, 30 KEV is used with a dose of 1E+14.

Still leaving the photoresist in place over the NMOS and PMOS devices, a layer of oxide 84 is grown over the EPROM cell to leave the structure as shown in FIGS. 14A, B and C.

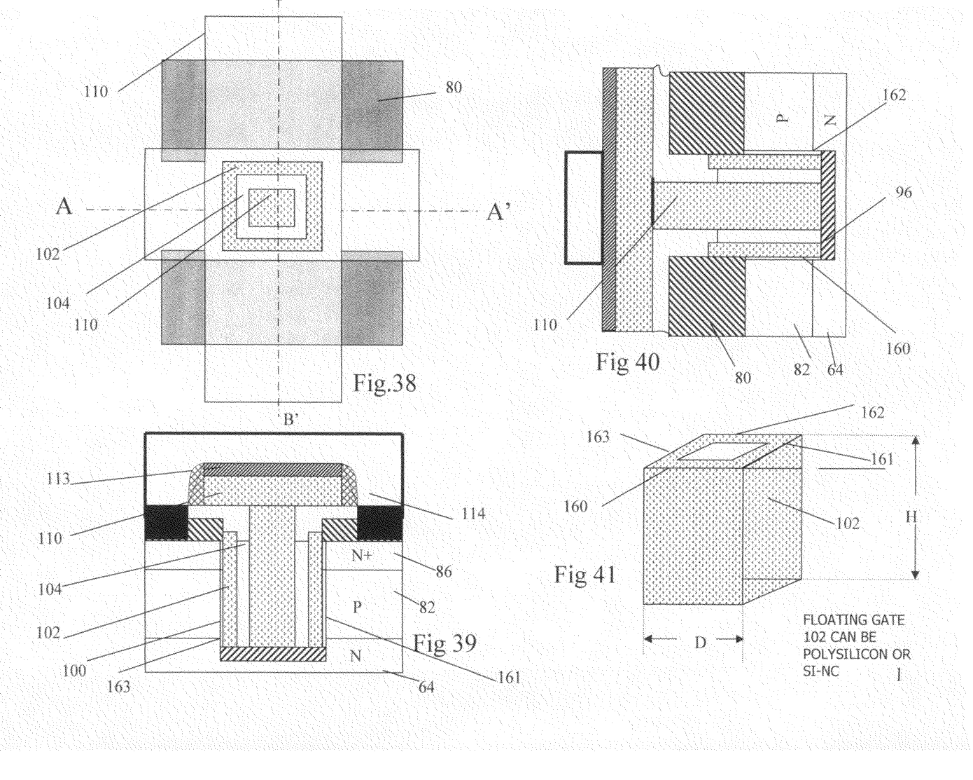

The EPROM cell area will be used to form two vertical EPROM devices. To start this process, a layer of photoresist (not shown) is deposited and a fifth mask is used to develop the photoresist so as to open two cell etch windows over the EPROM cell area. An anisotropic plasma etch process is then used to etch through the oxide layer 84 and etch down into the silicon to form two wells 88 and 90 also called recessed gate windows or trenches. These recessed gate windows must have sufficient depth to penetrate the N layer 86 and the P layer 82 and extend into the N well 64 of the EPROM cell. This leaves the structure as shown in FIGS. 15A, B and C. They can be square, round, oval or shaped like a polygon. Square is preferred for the deep field oxide improved embodiments shown starting at FIG. 38

A pad oxide layer (not shown) 300 angstroms thick is grown next. This layer covers the first nitride layer 68 over the NMOS and PMOS devices, the oxide layer 84 over the EPROM cells and covers the walls and bottoms of the recessed gate windows 88 and 90. This pad oxide layer protects the underlying structures from a second layer of nitride to be deposited next.

A second layer of nitride 92 approximately 500 angstroms thick is then deposited over the entire structure. This layer covers the walls and the bottom of the two recessed gate windows 88 and 90 and covers the top surface of the substrate.

An anisotropic etchback is then performed to remove all portions of nitride layer 92 on horizontal surfaces and leave only those portions on vertical surfaces, i.e., all nitride of layer 92 is removed except those portions on the vertical walls of the recessed gate windows to leave the structure as shown in FIGS. 17A, B and C.

Next, a layer of oxide insulator 96 is grown on the bottoms of the recessed gate windows. The nitride of layer 92 is then removed from the walls of the recessed gate windows 88 and 90 using a wet etch to leave the structure as shown in FIGS. 19A, B and C.

The pad oxide (not shown) underneath the second nitride layer 92 is then removed in a wet etch. Because the pad oxide layer was not separately shown, the structure after its removal looks as shown in FIGS. 19A, B and C.

A thin gate oxide layer 100 is then grown on the walls of the recessed gate windows 88 and 90 to insulate the polysilicon floating gate to be formed later from the silicon layers 86 (drain), 82 (channel) and 64 (source). Typically, this gate oxide is grown to a thickness of 90 to 100 angstroms in a process conventional to MOS devices.

Next, a layer of P type doped polysilicon 102 is deposited over the complete structure from which the self-aligned floating gate 22 in FIG. 5 will be formed to leave the structure as shown in FIGS. 20A, B and C. Typically, about 1000 angstroms of polysilicon is deposited and is doped P type with chemical dope of phosphorous either during or after deposition to a resistivity of 50 ohms per square.

To form the floating gate, the doped polysilicon is etched back off all horizontal surfaces and part way down into the recessed gate windows 88 and 90 to leave the segments of polysilicon shown at 102 in FIG. 21B. The remaining segments of poly 102 are self-aligned floating gates, and this is true in all EPROM embodiments disclosed herein. They are self-aligned because they were formed with an etchback and no mask or photolithography was necessary. This causes great savings in the area of each EPROM cell because the misalignment tolerances in the design rules that need to be respected in normal construction and which consume chip area in making each EPROM cell larger need not be respected in the vertical EPROM embodiments disclosed herein.

These segments of doped polysilicon 102 correspond to the floating gate 22 in the finished structure shown in FIG. 5 and are self aligned with the walls of the recessed gate windows 88 and 90 because no horizontal component of doped polysilicon is left on the surface of the substrate or on the bottom of the recessed gate windows which means no portion of the doped polysilicon will ever extend beyond the perimeter of the recessed gate window (see FIG. 21B for the configuration of the doped polysilicon floating gate 102 after the etchback). No mask is used for the etchback of the doped polysilicon layer 102 as can be seen from study of Table 1 steps 33 and 34 where no mask is recited as being used during the etchback. All steps that use masks are recited in Table 1 as using a mask and the mask number is given in the third column from the left.

Electrical isolation of the floating gate is accomplished by formation of another oxide-nitride-oxide layer 104 over the entire wafer to leave the structure as shown in FIGS. 22A, B and C. Typically, the ONO layer 104 is formed to a thickness of 150 angstroms by a conventional process.

At this point in the process, construction of the NMOS and PMOS devices is started in parallel with the completion of the EPROM devices. The first step in this process is to deposit a layer of photoresist and develop it with mask 6 to form an ONO protect mask 106 over the EPROM cell area as shown in FIG. 23B. Then an ONO etch and a nitride etch are performed to remove the ONO layer 104 and the nitride layer 68 over the NMOS and PMOS transistor active areas to leave the structure as shown in FIGS. 23A, B and C. The pad oxide (not shown) under the nitride layer 68 is left in place to protect the silicon from the threshold adjust implant to be performed next.

A threshold voltage adjustment is next performed by a conventional boron implant to implant charges into the surface region of the N well 62 and the P well 66 to adjust the voltages at which the PMOS and NMOS devices turn on. The design is such that one CMOS device threshold voltage is too low and the other CMOS device threshold voltage is too high before the threshold adjust implant. Then the threshold voltages are adjusted simultaneously in the proper directions by the threshold adjust implant.

After the implant, the pad oxide (not separately shown) that was under the oxide layer 68 is etched away to prepare the NMOS and PMOS devices for growth of a thin gate oxide. During this process the photoresist mask 106 is left in place to protect the EPROM cell area.

A thin gate oxide layer 108 is then grown over the N well 62 and the P well 66 to electrically insulate a gate electrode to be formed later from the underlying silicon. During this process the photoresist mask 106 is left in place to protect the EPROM cell area.

Next, the photoresist mask 106 is removed, and a second doped polysilicon layer 110 is deposited to a thickness of about 3000 angstroms. The control gates for the PMOS, NMOS and EPROM devices will be formed from this polysilicon layer 110. This second polysilicon layer also fills the recessed gate windows 88 and 90 and covers the ONO layer 104.

A thin layer of silicon dioxide 112 is then grown over the entire second polysilicon layer 110 to a depth of about 2000 angstroms.

A seventh mask is then used to develop a layer of photoresist deposited over the second polysilicon layer 110 and oxide 112 for purposes of etching the second polysilicon layer to form the control gates of the PMOS and NMOS devices and of the EPROM cells and the word lines corresponding to word line 28 in FIGS. 5 and 6. After the etch of the second polysilicon by a conventional process, the structure looks as shown in FIGS. 25A, B and C except that an LDD phosphorous implant to form the source and drain regions of the NMOS device has not yet been performed.

To form the source and drain regions of the NMOS devices, an 8th mask is used to develop a layer of photoresist to form an LDD implant mask over the PMOS and EPROM devices. Then phosphorous is implanted in a conventional process using the etched second polysilicon layer 110 over the NMOS device as a mask to form self aligned LDD regions (lightly doped drain regions) shown at 114 in FIG. 25A. Later, more heavily doped, deep source and drain regions will be formed, but the LDD implants prevent short channel problems.

To protect the sidewalls of the control gates of the NMOS, PMOS and EPROM devices, a spacer oxide deposition is performed to a depth of 3000 angstroms and then the spacer oxide is etched back to form the spacer oxide regions 114 on the sidewalls of the polysilicon control gates formed from second polysilicon layer 110. The spacer etch is an anisotropic etch to remove the spacer oxide from only the horizontal surfaces.

Referring to FIGS. 27A, B and C, to open contact holes 118 and 120 to the EPROM cell, a layer of photoresist is deposited and developed with a ninth mask to form a cell contact etch mask layer 116 protecting the PMOS and NMOS devices. The developed photoresist of layer 116 is also located so as to bound the outer limits of the contact holes to be etched through the ONO layer 104 and the oxide layer 84. The other boundaries of these contact holes are self aligned with the outer edges of the spacer oxide 114. Oxide layers 113 are then formed on top of the second polysilicon control gates 110 using the photoresist 116 as a mask as shown in FIG. 28B.

The ONO etch and oxide etch is then performed to leave the structure as shown in FIGS. 27A, B and C with contact holes 118 and 120 to the N type layer 86 for the bit line connections (not shown).

To form the bit lines corresponding to the bit line 30 in FIGS. 5 and 6, a layer of metal or polysilicon 122 is deposited over the structure. Metal is shown at 122 in FIG. 28B, but doped polysilicon is preferred for better step coverage.

Photoresist is then deposited and a tenth mask is used to develop it to form a protective layer over the EPROM devices so as to allow removal of the metal or polysilicon off the NMOS and PMOS devices and so as to define the outlines of the bit lines. The metal or polysilicon 122 is then etched into the shape of the bit lines and removed from over the PMOS and NMOS devices to leave the structure as shown in FIGS. 28A, B and C.

Next, to complete the NMOS device, an N+arsenic implant must be performed in the P well. To accomplish this, a layer of photoresist is deposited and developed with an eleventh mask to protect the EPROM cell and the PMOS active area by photoresist which is not shown in these figures. An N+ arsenic implant is then performed using this photoresist exposing the P well and the polysilicon 110 and the spacer oxide 114 as a mask to form the self-aligned source and drain regions 130 and 132.

To complete the PMOS device, another layer of photoresist is deposited and developed with mask 12 to expose the N well 62 and protect the EPROM active area and the P well 66. A P+ boron implant is then performed using this photoresist as a mask and the second polysilicon control gate 110 and spacer oxide 114 as a mask to form self-aligned source and drain regions 134 and 136. This leaves the structure as shown in FIGS. 29A, B and C.

To repair the implant damage, the structure is annealed at 1000 centigrade for 30 seconds.

To passivate the structure, a BPSG deposition is performed to a thickness of 6000 angstroms.

To complete the NMOS and PMOS devices, contacts to the source and drains of the PMOS and NMOS devices must be made. To do this, a layer of photoresist is deposited and developed using contact mask 13. An etch is then performed to cut the contact holes 138, 140, 142 and 144 through the BPSG layer 146.

After a contact reflow to soften the edges for better step coverage, a layer of metal is then deposited to 7000 angstroms and etched to form the contacts 148, 150, 152 and 154 to complete the structure as shown in FIGS. 31A, B and C.

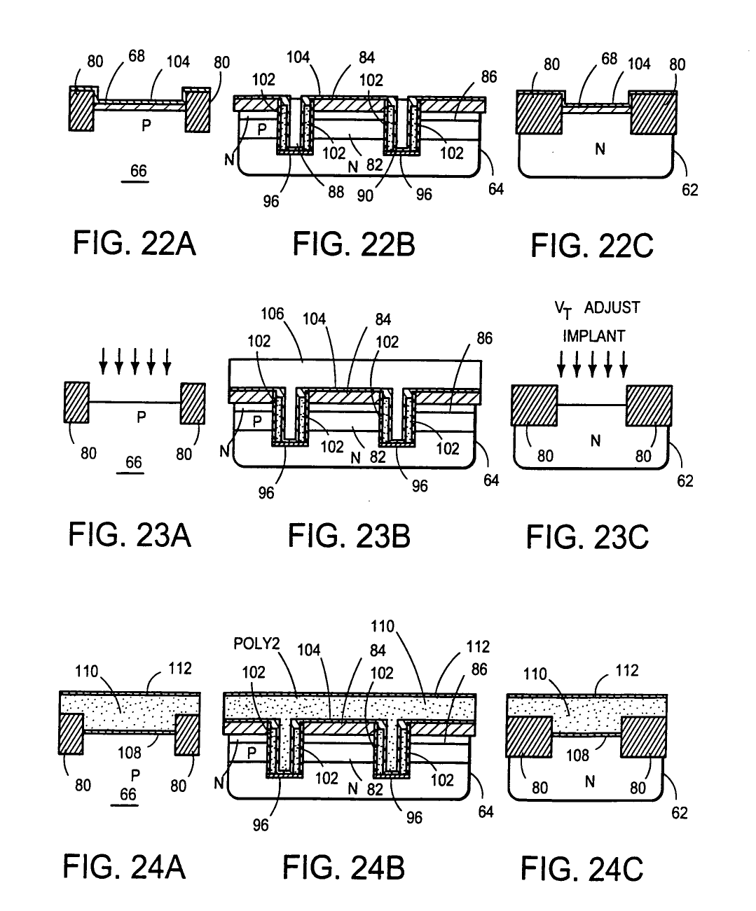

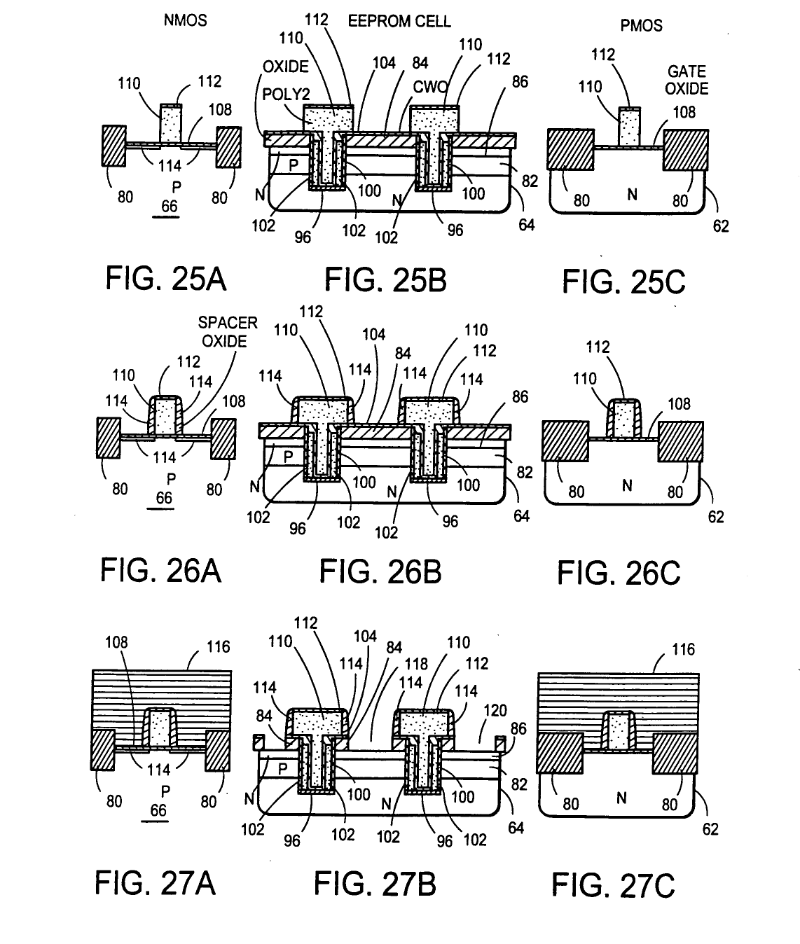

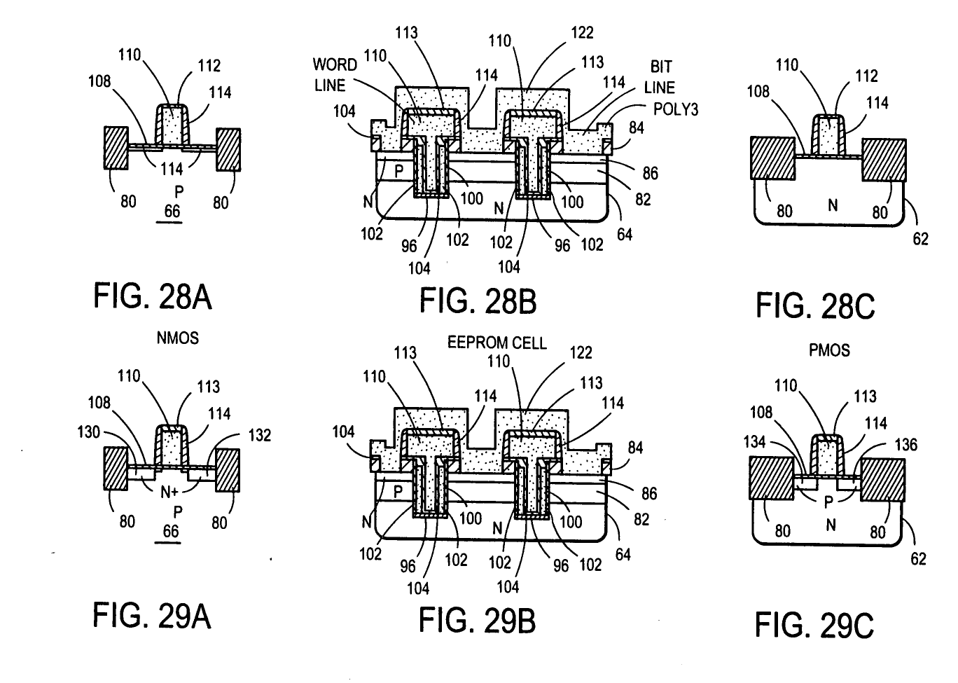

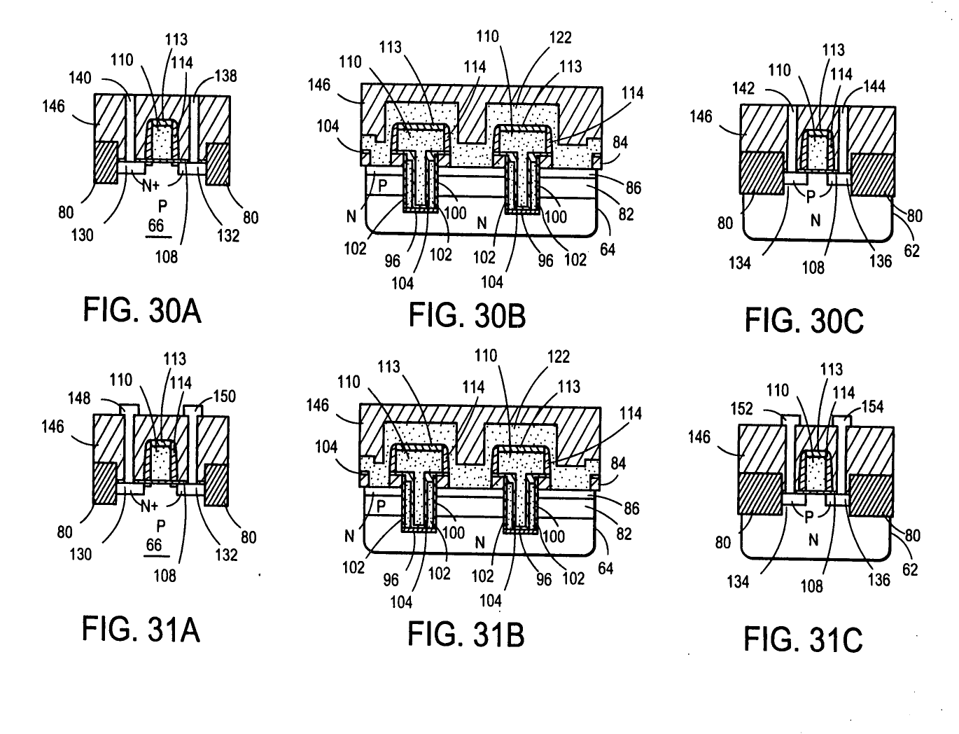

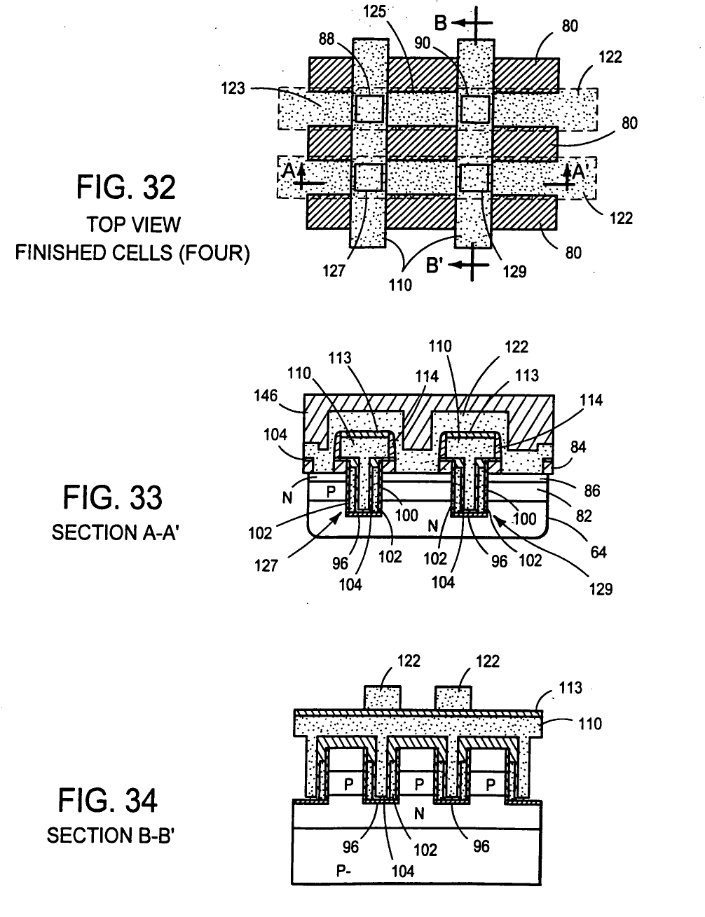

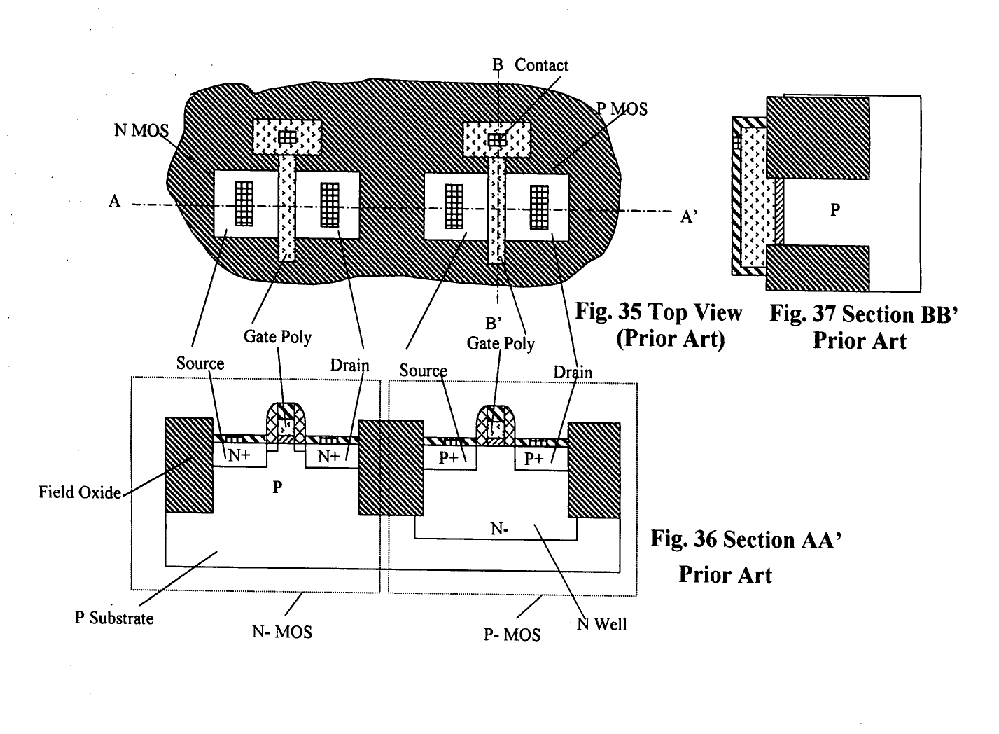

Referring to FIG. 32, there is shown a plan view of four cells in an array of vertically oriented EPROM cells according to the teachings of the invention and constructed according to a process which is compatible with the simultaneous formation of CMOS devices on the same die. The outlines of two recessed gate windows in which two EPROM cells are formed are shown at 88 and 90. First polysilicon word lines are shown at 110. The metal or second polysilicon bit lines are shown at 122. The drain regions of the EPROM cells are shown at 123 and 125.

FIG. 33 is a cross-sectional view taken along section line A-A′ in FIG. 32 of the lower two EPROM cells having recessed gate windows shown at 127 and 129 in FIG. 32. FIG. 34 is a cross-sectional view of the EPROM cells in recessed gate windows 90 and 129 in FIG. 32 taken along section line B-B′ therein. Structural elements in FIGS. 33 and 34 corresponding to elements in FIGS. 7A, B and C through FIGS. 31A, B and C and FIG. 32 have the same reference numerals.

There is given below a table summarizing the above described process of building the flash EPROM according to the teachings of the invention which is compatible with simultaneous fabrication of CMOS devices on the same die.

TABLE 1
PROCESS FLOW FOR CONSTRUCTING A SELF-ALIGNED EPROM
MEMORY CELL COMPATIBLE WITH CMOS DRIVERS ON THE SAME DIE

| STEP | DETAILS | MASK | FIG. |
|---|---|---|---|
| 1. Start with silicon substrate | P-Type, Resistivity | | |
| 2. Grow a layer of oxide | Approx. 300 | | |
| | angstroms | | |
| 3. Deposit a layer of nitride | Approx. 1000 | | |
| | angstroms | | |
| 4. Deposit and develop a layer of photoresist | | Mask 1 | |
| using twin well mask | | | |
| 5. Etch nitride layer over portion of substrate | | | |
| to become N-wells 62 and 64 | | | |
| 6. Form N-wells 62 and 64 with phosphorous | 3000 anstroms deep, | | |
| implant | conventional dosage | | |
| 7. Drive phosphorous and re-oxidize N-wells | 1000 degrees C., 1 | | |
| 62 and 64 | hour | | |
| 8. Strip photoresist and nitride | | | |
| 9. Implant Boron to form P-well 66 | | | |
| 10. Drive the N and P wells 62, 64 and 66 | 1100 degrees C., 5 | | FIGS. 7A, |
| deeper | hours, 5-6 microns | | B and C |
| | deep after drive | | |
| 11. Etch oxide over N-wells 62 and 64 to | | | |
| clear the surface thereof for further | | | |
| processing | | | |
| 12. Grow pad oxide | 300 angstroms | | |
| 13. Deposit nitride layer | 1000 angstroms | | |
| 14. Deposit photoresist and use active mask | | Mask 2 | FIGS. |
| to develop photoresist to define etch masks | | | 8A, B and C |
| 70, 72, 74 for active areas | | | |
| 15. Etch oxide/nitride layer 68 to define | | | FIGS. |
| active areas | | | 9A, B and C |
| 16. Deposit a layer of photoresist and | | Mask 3 | FIGS. |
| develop using a field implant mask to form | | | 10A, B and C |
| field implant mask 76 | | | |
| 17. Boron implant to deposit field implant | Conventional dosage | | |
| impurities in P well. | and energy | | |
| 18. Grow field oxide | 6000 angstroms | | FIGS. |
| | | | 11A, B and C |
| 19. Deposit photoresist and develop with | | Mask 4 | |
| mask 4 to leave exposed only the ONO layer | | | |
| 68 over the EPROM cells | | | |
| 20. Etch away nitride portion of | | | FIGS. |
| oxidie/nitride layer 68 over EPROM cell to | | | 12A, B and C |
| leave pad oxide | | | |
| 21. Implant boron to form P region 82 below | 100 KEV, 1E+12 | | |
| substrate surface throughout N well in which | | | |
| EPROM is to be formed to make channel | | | |
| region 12 of finished device as shown in | | | |
| FIG. 5. | | | |
| 22. Implant arsenic to redope to N type | 30 KEV, 1E+14 | | FIGS. |
| region 86 below surface but above P layer | | | 13A, B and C |
| 82 | | | |
| 23. Grow layer of oxide 84 over EPROM cell | 2000 angstroms | | FIGS. |
| area | | | 14A, B and C |
| 24. Deposit layer of photoresist and use cell | | Mask 5 | |
| etch mask 5 to develop to open windows for | | | |
| etching recessed gate windows 88 and 90 | | | |
| 25. Anisotropically etch recessed gate | | | FIGS. |
| windows 88 and 90 through N layer 86 and | | | 15A, B and C |
| P layer 82 into N well 64 | | | |
| 26. Grow pad oxide layer over whole | 300 angstroms | | |
| substrate to protect underlying structures | | | |
| from second nitride layer | | | |
| 27. Deposit second nitride layer 92 which is | 500 angstroms | | FIGS. |
| thinner than first nitride layer 68 | | | 16A, B and C |
| 28. Perform anisotropic nitride etchback to | anisotropic etch | | FIGS. |
| remove nitride of layer 92 on all horizontal | | | 17A, B and C |
| surfaces and leave it covering only the | | | |
| vertical walls of the recessed gate windows | | | |
| 88 and 90 | | | |
| 29. Grow oxide 96 on bottoms of recessed | 2000 angstroms | | FIGS. |
| gate windows | | | 18A, B and C |
| 30. Cell nitride strip using a wet etch to | dip off nitride in wet | | FIGS. |
| remove nitride layer 92 from walls of | etch | | 19A, B and C |
| recessed gate windows 88 and 90. | | | |
| 31. Pad oxide strip | dip off pad oxide in | | |
| | wet etch | | |
| 32. Grow thin gate oxide layer 100 | 90-100 angstroms, | | |
| | conventional process | | |
| 33. Deposit doped polysilicon layer 102 from | 1000 angstroms | | FIGS. |
| which floating gate is to be formed | doped P type to 50 | | 20A, B and C |
| | ohms per square | | |
| 34. Etch back doped polysilicon layer 102 | | | FIGS. |
| from horizontal surfaces to leave floating | | | 21A, B and C |
| gates | | | |
| 35. Form Oxide-Nitride-Oxide layer 104 | Conventional process, | | FIGS. |
| above floating gates | 150 angstroms | | 22A, B and C |
| 36. Form ONO protect mask 106 | | Mask 6 | |
| 37. ONO etch, nitride etch to clear PMOS | | | FIGS. |
| and NMOS active areas for transistor | | | 23A, B and C |
| formation. | | | |
| 38. Threshold voltage adjust implant | Boron | | |
| 39. Leaving photoresist mask 106 in place, | | | |
| etch away pad oxide under first nitride layer | | | |
| 68 to expose N well and P well silicon | | | |
| 40. Leaving photoresist mask 106 in place, | 150 angstroms | | |
| grow thin gate oxide 108 over N well 62 and | | | |
| P well 66 | | | |
| 41. Remove photoresist mask 106, and | 3000 angstroms | | |
| deposit a doped second polysilicon layer 110 | | | |
| over entire structure | | | |
| 42. Oxidize second polysilicon | 2000 angstroms | | FIGS. |
| | | | 24A, B and C |
| 43. Deposit photoresist, and use 7th mask to | | Mask 7 | |
| develop a second poly etch mask | | | |
| 44. Etch second polysilicon 110 and | | | |
| overlying oxide to form control gates and | | | |
| word lines corresponding to word line 28 in | | | |
| finished device of FIG. 5 | | | |
| 45. Deposit photoresist and develop using | | Mask 8 | |
| 8th mask to protect PMOS and EPROM | | | |
| devices to form LDD implant mask | | | |
| 46. Phosphorous LDD implant using control | Conventional process | | FIGS. |
| gate poly as a mask to form self-aligned LDD | | | 25A, B and C |
| source and drain regions of NMOS devices. | | | |
| 47. Deposit spacer oxide | 3000 angstroms | | |
| 48. Anisotropically etch spacer oxide to leave | | | FIGS. |
| spacers on sidewalls of polysilicon control | | | 26A, B and C |
| gates. | | | |
| 49. Deposit photoresist and develop with | | Mask 9 | FIGS. |
| Mask 9 to protect the NMOS and PMOS | | | 27A, B and C |
| devices for a bit line contact hole etch and | | | |
| reoxidize tops of second polysilicon 110 to | | | |
| form oxide layer 113 | | | |
| 50. Etch self aligned bit line contact holes | | | |
| 118 and 120 through ONO 104 and oxide 84 | | | |
| 51. Deposit bit line metal orpoly 122 | 5000 angstroms | | |
| 52. Deposit layer of photoresist and develop | | Mask 10 | |
| using 10th mask to form protective mask | | | |
| layer over NMOS and PMOS devices | | | |
| 53. Etch bit line metal layer 122 to form bit | | | |
| lines | | | |
| 54. Deposit photoresist and develop using | | Mask 11 | |
| mask 11 to expose N well 62 and protect | | | |
| EPROM active area 64 and P well 66 of | | | |
| NMOS device. An N+ arsenic implant is then | | | |
| performed using this photoresist exposing | | | |
| the P well and the polysilicon 110 and the | | | |
| spacer oxide 114 as a mask to form self- | | | |
| aligned source and drain regions 130 and | | | |
| 132. | | | |
| 55. A P+ boron implant is then performed to | | Mask 12 | |
| form self aligned source and drain regions | | | |
| 134 and 136 of PMOS device. | | | |
| | | | FIGS. |
| | | | 29A, B and C |
| 55. Anneal implants | 1000 C., 30 sec | | |
| 56. BPSG passivation deposition | 6000 angstroms | | |
| 57. Deposit photoresist and develop with | | Mask 13 | |
| contact mask 13 to form mask for contact | | | |
| holes for NMOS and PMOS devices | | | |
| 58. Etch contact holes | | | |
| 59. Contact reflow | | Mask 14 | |
| 60. Metal deposition, mask and etch to form | 7000 angstroms | Mask 15 | FIGS. |
| contacts 148, 150, 152 and 154 | | | 31A, B and C |

### New Embodiments with Deep Field Oxide to Lower C1 and Increase and Maintain Coupling Ratio Above 50% as Feature Size is Scaled Down

As described earlier in paragraph [0019] and [0021] in U.S. patent publication US2002/0096703 (the parent application of which this is a continuation-in-part), the coupling ratio is an important parameter for the ‘write’ operation of an EPROM. Typically the coupling ratio is 0.5 or better (50% or better) in state of the art flash EPROM cells. The reason this is preferred is to lower programming voltage so that smaller thickness insulation layers can be used without fear of “punch through” which could destroy the device. Smaller structures mean greater density. This means that if the ‘write’ voltage needed at the gate is 7 volt then a voltage of 14 volts is needed at the control gate to ‘write’ the cell meaning inject charge on the floating gate by hot electron injection. A method of calculating the coupling ratio for the structure in the FIG. 32, FIG. 33 and FIG. 34 of the parent application is described below:

FIG. 32 shows the top view of an array of 4 cells. FIG. 33 shows the section along AA′ of FIG. 32, and FIG. 34 shows the section along BB′ of FIG. 32. New FIG. 38 enclosed herewith shows a detailed top view of one of the 4 cells of FIG. 32 (there is no new subject matter over the parent application in FIGS. 38-41—these figures are just enlarged views to aid in illustrating the coupling ratio calculation described below). FIG. 39 shows the section of FIG. 38 along section line AA′. FIG. 40 shows the section of FIG. 38 along section line BB′. FIG. 41 shows a 3 dimensional view of the floating poly gate 102 in FIG. 38, and shows the ONO (Oxide/Nitride/ONO) insulator layer 104 inside the vertical recess or well. Vertical, as the term is used herein, means a well having a long axis which is orthogonal to the top surface of the substrate. The well looks like a square tube with a composite wall of Polysilicon 102 on outside and ONO insulator 104 on the inside. The well (hereafter referred to as the recess) has four sides 160,161,162 and 163 as best seen in FIG. 41. Sides 161 and 163 form an active vertically oriented EPROM transistor as shown in FIG. 39 with source 64, and drain 86 and channel region 82 having its conductivity controlled by the floating gate 102 and thin gate oxide 100. Sides 160 and 162 do not form active transistors because field oxide 80 (seen best in FIG. 40) penetrates into the substrate silicon and prevents any formation of a drain region. Therefore, sides 160 and 162 form only parasitic capacitors consisting of the capacitance between floating gate 102 and P substrate 82.

The coupling ratio R for the parent application structure shown in FIGS. 38-41 is given by C2/(C2+C1) where C2 is the capacitance between control gate poly 110 and floating gate poly 102 separated by ONO (Oxide/Nitride/Oxide) 104. C1 is the capacitance between floating gate poly 102 and the p substrate 82 separated by thin gate oxide 100 as best seen in FIG. 39. All four sides 160,161,162 and 163 of the recess contribute to C1 and C2.

R=C2/(C2+C1)

C1=K₁·A₁/t₁

C2=K₂·A₂/t₂

### Where,

K₁ is the dielectric constant of SiO₂
K₂ is the dielectric constant of ONO
t₁ is the thickness of SiO₂ 100
t₂ is the thickness of ONO 104
A₁=the area of the outside surface of Poly in the tube of FIG. 41
A₂ is the area of the inside surface of ONO in the tube of FIG. 41

### And,

A₁=4·H·D

A₂=4·H(D−t₂−t₃)

### Where

H is the height of the tube of FIG. 41
D is the dimension of one side of the square tube in FIG. 41
t₃ is the thickness of the floating gate poly 102

The calculated value of the coupling ratio, R is described in the table below for typical dimensions and parameters listed above for 0.18 micron and 0.065 micron lithography features for the structure in FIG. 38, FIG. 39 and FIG. 40.

Calculation of Coupling Ratio, R for the Structure in FIG. 38, FIG. 39 and FIG. 40.

| Lithography Features | | 0.18 | 0.13 | 0.065 | □ |
|---|---|---|---|---|---|
| Height of the recess | H | 4000 | 4000 | 4000 | A^{o} |
| Side of the recess | D | 1800 | 1300 | 650 | A^{o} |
| Thickness of Poly | t₃ | 200 | 200 | 200 | A^{o} |
| Thickness of gate oxide | t₁ | 80 | 80 | 80 | A^{o} |
| Thickness of the ONO | t₂ | 120 | 120 | 120 | A^{o} |
| Dielectric constant of SiO2 | K₁ | 3.36E−13 | 3.36E−13 | 3.36E−13 | Fcm⁻¹ |
| Dielectric constant of ONO | K₂ | 6.64E−13 | 6.64E−13 | 6.64E−13 | Fcm⁻¹ |
| Area of the outer surface of Poly | A₁ | 0.29 | 0.208 | 0.104 | □^{□} |
| Area of the inner surface of ONO | A₂ | 0.24 | 0.16 | 0.05 | □^{□} |
| Floating gate and P layer | C₁ | 1.21 | 0.87 | 0.44 | fF |
| capacitance | | | | | |
| Control gate and floating gate | C₂ | 1.31 | 0.87 | 0.29 | fF |
| capacitance | | | | | |
| Coupling Ratio | R | 52% | 50% | 40% | |

It can be seen from the table above that R for 0.18□ (0.18 micron) features in the structures of FIGS. 38-41 is similar to state of the art EPROM structures. This means that if 14V is applied to control gate 110, 7 volts will appear across the gap between the floating gate 102 and the substrate. This is sufficient for write operations. However, as the size of features are scaled downward in the table above, the coupling ratio R goes below 50% as one approaches feature sizes of 0.065 microns (40% coupling ratio to be exact and even less when smaller features than 0.065 microns are achievable). This smaller coupling ratio is undesirable because it means that much higher voltages than 14 volts are needed for ‘write’ operation. This is not desirable because of the punch through problem mentioned above.

Accordingly, there is a need for a slightly different structure for the vertically oriented EPROM cell described herein which will maintain a coupling ratio R above 50% for all the future scaled lithography features.

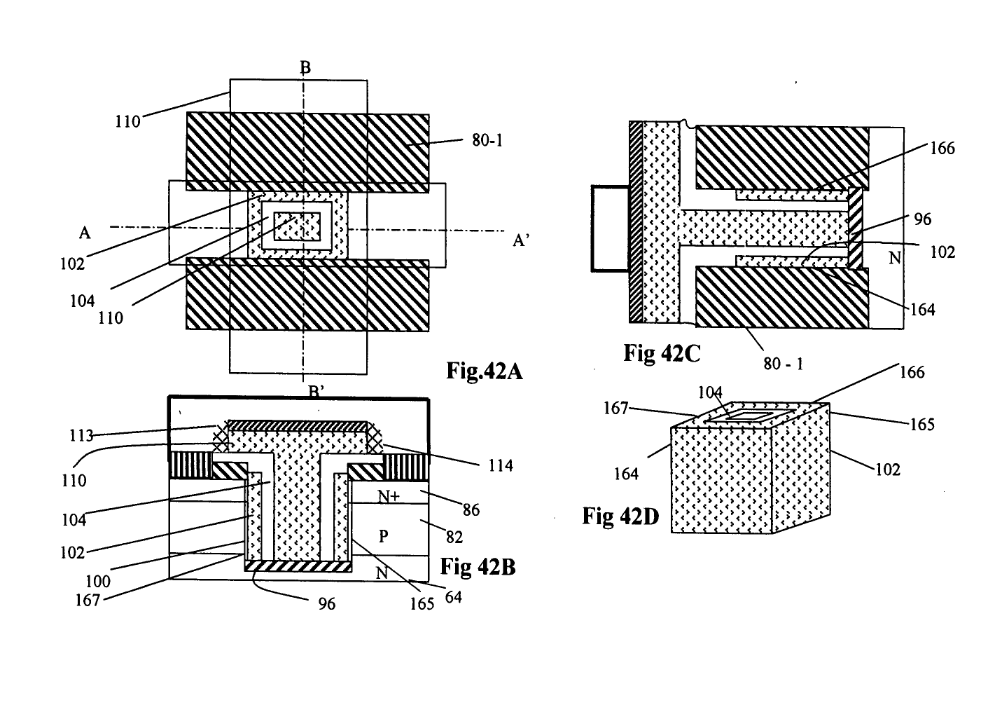

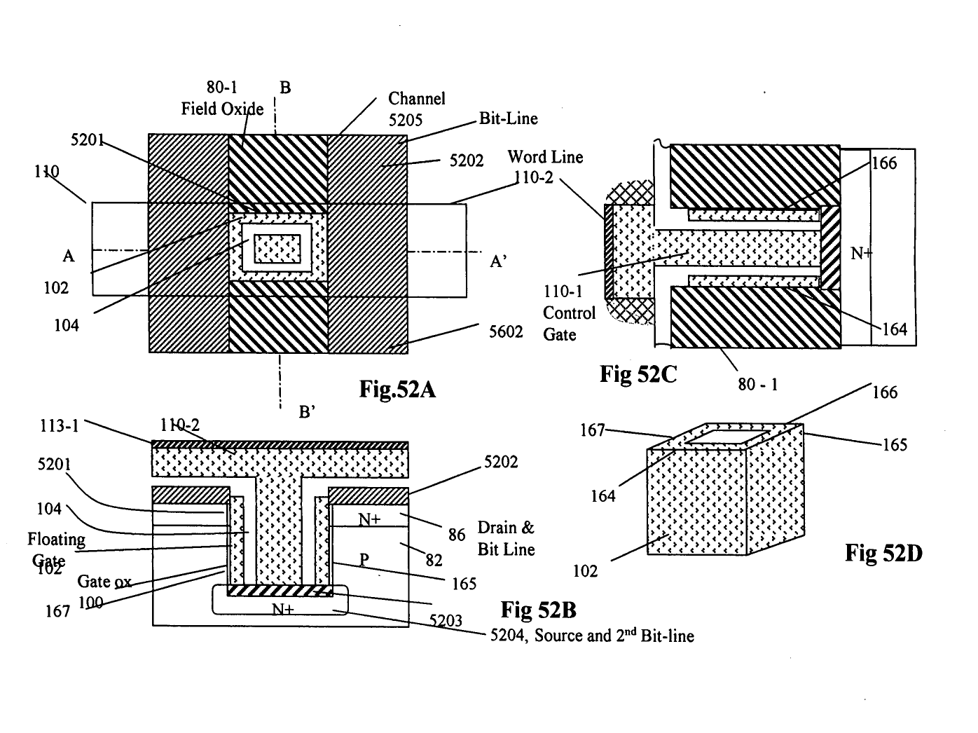

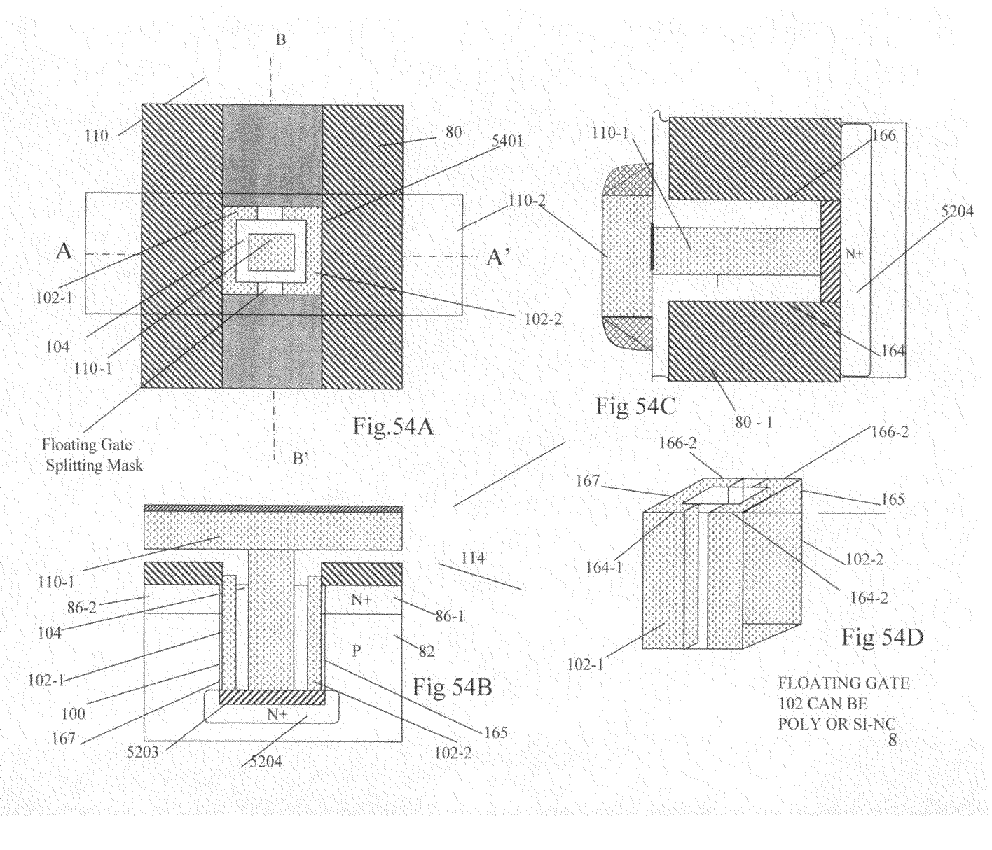

FIGS. 42A, 42B and 42C show the structure for one species of the class of embodiments which maintain R above 50% as feature sizes get smaller. The only change is that the thickness of the field oxide 80-1 is increased so as to reduce the parasitic capacitance contributed by sides 164 and 166 in FIG. 42D (which correspond to sides 160 and 162 in FIG. 41) Field oxide 80-1 in FIG. 42C is deeper than the field oxide 80 in FIG. 40. Field oxide 80-1 extends well below all of the floating gate 102 and the oxide 96 at the bottom of the recess, as best seen in FIG. 42C. There are four sides to the recess 164,165,166 and 167 in FIGS. 42B, 42C and 42D. Sides 165 and 167 form the vertical EPROM active transistor, as best seen in FIG. 42B. As was the case for FIG. 39, this active vertically oriented transistor has source region 64, drain region 86, floating gate 102, control gate 110, and channel region 82 below floating gate 102 and gate oxide 100. When charge storage conditions on floating gate 102 are such that the threshold of the transistor is exceeded when voltage is put on the control gate, a conductive channel forms in channel region 82 and current can flow between the source and drain if proper voltage differential to read the cell are applied between the bit line (coupled to the drain region 86 but not shown) and the substrate. The vertically oriented EPROM transistors of FIGS. 52A and 54A work the same way.

To reduce the parasitic capacitance added by sides 164 and 166, field oxide 80-1 is formed on the sides 164 and 166 so as to extend well below bottom oxide 96 and thus virtually eliminates the sidewall capacitance between the floating gate and the substrate which is present and appreciable in the structure of FIGS. 38-41. So C1, the capacitance between floating gate 102 and P substrate 82, separated by thin gate oxide layer 100, is determined by only two sides, 165 and 167, the sides forming the active transistor. This results in a major reduction in C1. The capacitance C2 between control gate 110 and the floating gate 102 is still determined by the area of all four sides 164,165,166 and 167. Hence this extended field oxide 80-1 is expected to give much higher coupling ratio R.

Of course in alternative embodiments, more than four or less than four sides may be used or a round or oval recess may be used. It is only important for purposes of practicing the invention that at least part of the circumference of the trench be bounded by field oxide which extends down into the substrate far enough to extend past the bottom of the recess. Preferably, at least half the circumference of the recess will be bounded by field oxide and the other half will be bounded by doped semiconductor so as to form an active vertically oriented EPROM transistor. The important thing is that the portion of said circumference which is bounded by field oxide so as to reduce C1 is enough that C1 is reduced sufficiently to cause the coupling ratio to remain high enough that a programming voltage can be applied which is low enough to not cause punch through for the desired feature sizes. Generally, a coupling ratio above 50% is desirable, but coupling ratios can be less than 50% so long as the programming voltage can be kept low enough to prevent punch through. This condition must remain true as feature sizes are scaled down, so the higher the coupling ratio can be, the better is the programming voltage criteria as feature sizes are scaled down. Lower programming voltages at smaller feature sizes is desirable because the thickness of insulating layers also gets smaller thereby creating a danger of punch through.

The equations for calculating R are as below.

R=C2/(C2+C1)

C1=K₁·A₁/t₁

C2=K₂·A₂/t₂

### Where,

K₁ is the dielectric constant of SiO2
K₂ is the dielectric constant of ONO
t₁ is the thickness of SiO2 100
t₂ is the thickness of ONO 104
A₁=the area of the outside surface of poly in the tube of FIG. 41
A₂ is the area of the inside surface of ONO in the tube of FIG. 41

### And,

A₁=2·H·D

A₂=4·H(D−t₂−t₃)

### Where

H is the height of the tube of FIG. 41
D is the dimension of one side of the square tube in FIG. 41
t₃ is the thickness of the poly 103

Note by comparison that the value for A₁ in this embodiment is twice as small as for the embodiment shown in FIGS. 38-41.

The calculated value of the coupling ratio, R, is described in table below for typical dimensions and parameters listed above for 0.18 micron, 0.13 micron and 0.065 micron lithography features for the structure in FIGS. 42A, 42B and 42C.

Calculation of Coupling Ratio, R for the Structure in FIGS. 42A, 42B and 42C.

| Lithography Features | | 0.18 | 0.13 | 0.065 | □ |
|---|---|---|---|---|---|
| Height of the recess | H | 4000 | 4000 | 4000 | A^{o} |
| Side of the recess | D | 1800 | 1300 | 650 | A^{o} |
| Thickness of Poly | t₃ | 200 | 200 | 200 | A^{o} |
| Thickness of gate oxide | t₁ | 80 | 80 | 80 | A^{o} |
| Thickness of the ONO | t₂ | 120 | 120 | 120 | A^{o} |
| Dielectric constant of SiO2 | K₁ | 3.36E−13 | 3.36E−13 | 3.36E−13 | Fcm⁻¹ |
| Dielectric constant of ONO | K₂ | 6.64E−13 | 6.64E−13 | 6.64E−13 | Fcm⁻¹ |
| Area of the outer surface of Poly | A₁ | 0.14 | 0.104 | 0.052 | □^{□} |
| Area of the inner surface of ONO | A₂ | 0.24 | 0.16 | 0.05 | □^{□} |
| Capacitance between Floating gate | C₁ | 0.61 | 0.44 | 0.22 | fF |
| poly and P Substrate | | | | | |
| Capacitance between Control gate | C₂ | 1.31 | 0.87 | 0.29 | fF |
| and floating gate | | | | | |
| Coupling Ration | R | 68% | 66% | 57% | |

The table given above shows that the presence of field oxide 80-1 bordering sidewalls 164 and 166 reduces C1 dramatically thereby increasing R significantly.

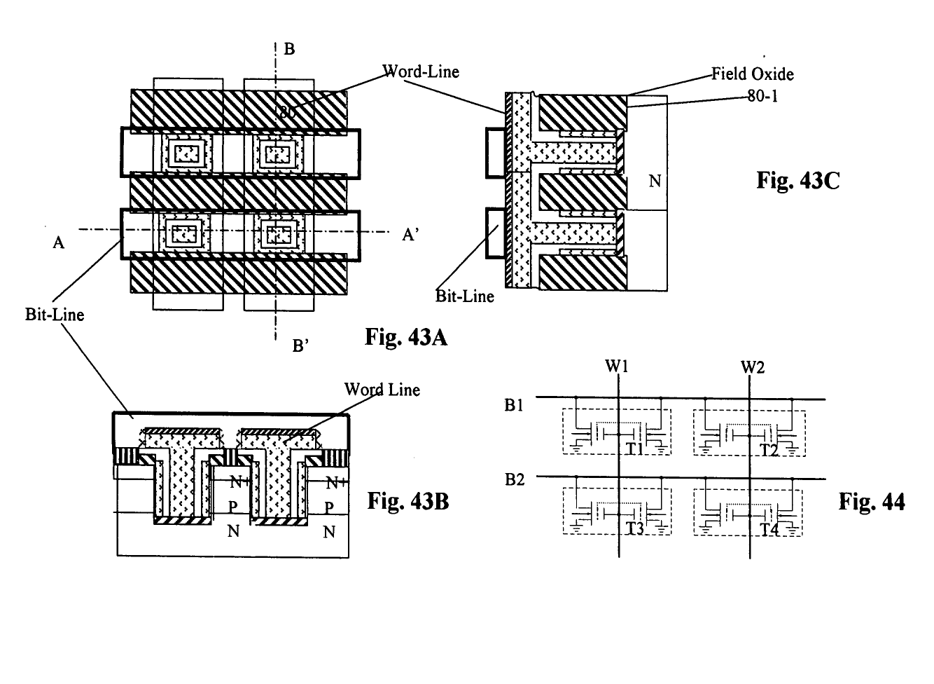

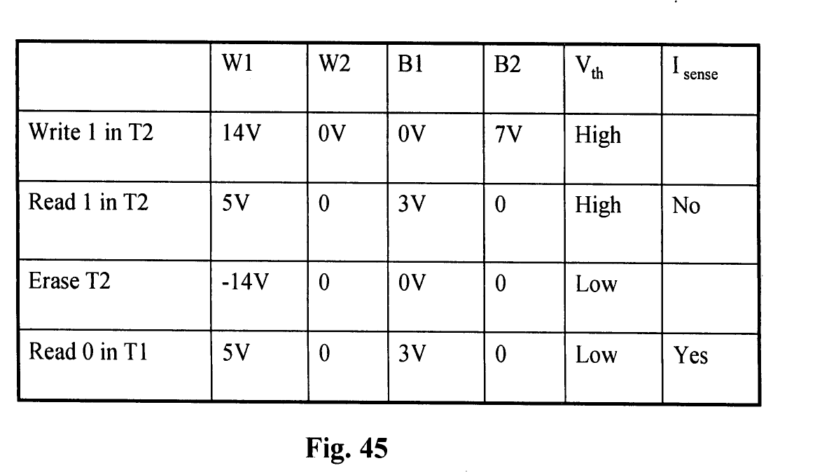

An array of 2×2 EPROM transistors is shown in FIGS. 43A, 43B and 43C. FIG. 43A is the top view. FIG. 43B is the section along AA′ of FIG. 43A. FIG. 43C is the section along BB′ of FIG. 43A. FIG. 43D is the equivalent circuit of the array showing connection of transistors with bit-lines and word-line B1, B2, W1 and W2. The operation of this circuit similar to industry standards NOR organization of an EPROM array. The key advantage of this embodiment is the deeper field oxide 80-1 in FIG. 43C.

There are several methods that enable field oxide 80-1 in FIG. 42C to extend below bottom oxide 96. One of the methods is described below.

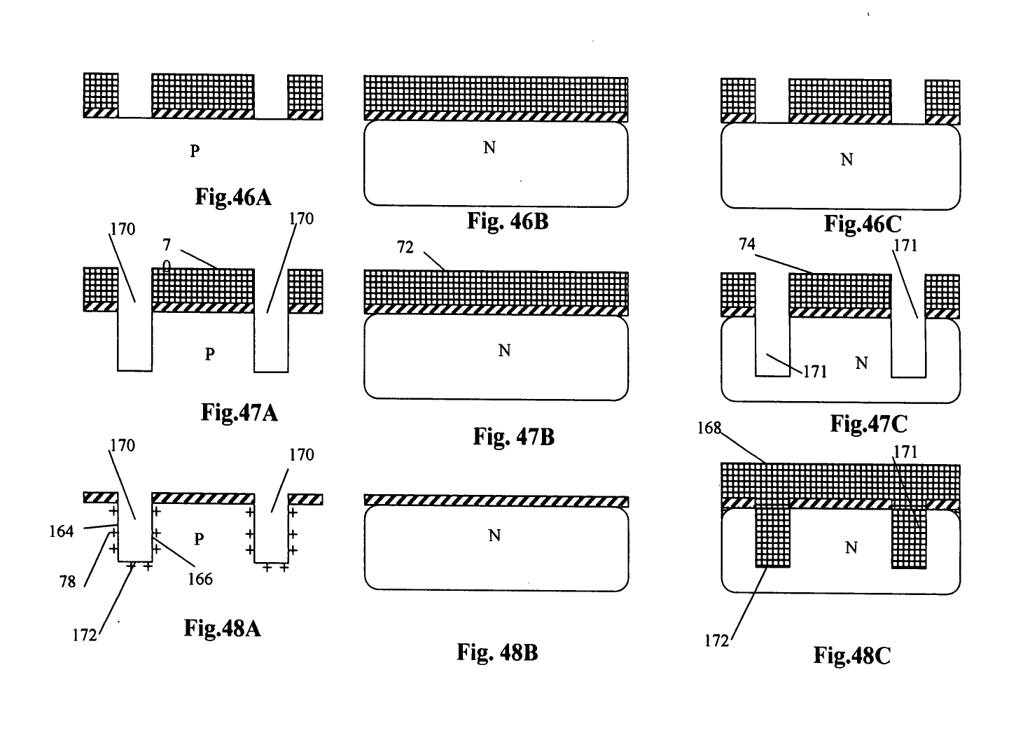

Silicon is processed as shown in FIGS. 7A, B and C and FIGS. 8A, B and C from the parent application. Processing is the same as previously described for the parent application up through the processing of FIGS. 7A, B and C and FIGS. 8A, B and C. Processing for the rest of the process up to a point to be described below proceeds as shown in FIGS. 46A, B and C through FIGS. 51A, B and C to form trenches in which deep field oxide will be formed to reduce the value of C1 on at least two sides of the recess. Thereafter, processing picks up at FIGS. 12A, B and C through FIG. 34 of the parent case.

FIGS. 46A, B and C show the removal of nitride/oxide layer 68 in the areas where field oxide 80 or 80-1 is to be formed. Understand that the trenches to be described below in which the deep field oxide deposits are to be made are not only formed in the PMOS and NMOS transistor areas of FIGS. 46A-51A and FIGS. 46C-51C but also in the EPROM cell area of FIGS. 46B-51B. The reason the deep field oxide trenches do not appear in FIGS. 46B-51B is because these figures are sections along section line AA′ in FIG. 43A where active devices are formed alongside the recessed gate windows. If these sections had been taken along section line BB′ in FIG. 43A, the deep field oxide trenches in which deep field oxide 80-1, etc. are formed would show like they show in FIG. 43C.

Gaps 170 and 171 are formed in photoresist layer 70, 72 and 74 (the gap in layer 72 cannot be seen in FIGS. 46B and 47B because it is out of the plane of the section, i.e., it is down into the page). After forming these photoresist gaps, the next step is to etch the substrate silicon anisotropically to form trenches 170, 171 as shown in FIGS. 47A, B and C. These trenches are where the deep field oxide that isolate the NMOS and PMOS devices that are being formed on the same die as the EPROM cells to do such auxiliary functions such as sense amplifiers etc. Other trenches not shown in FIGS. 46B through 51B (because they are out of the plane of the section) border on two sides of each EPROM cell recessed gate window (also referred to herein as a well or trench). The field oxide to be formed in these trenches isolates the EPROM cells as well as reduce the value of C1 to improve the coupling ratio as cell features sizes are reduced with improved processing techniques.

Next, a photo resist layer 168 is formed to protect the PMOS transistor (FIGS. 48A, 48B and 48C) from a P implant.

Next, a field implant of P type impurities (symbolized by + signs 78 along the walls of recess 170) is implanted at an angle so the sidewalls and bottom of the field oxide trenches are doped as shown in FIGS. 48A, B and C. This same doping occurs in the field oxide trenches (not shown in FIGS. 46B-51B) adjacent the positions where the EPROM cell recessed gate windows will be formed later in the process.

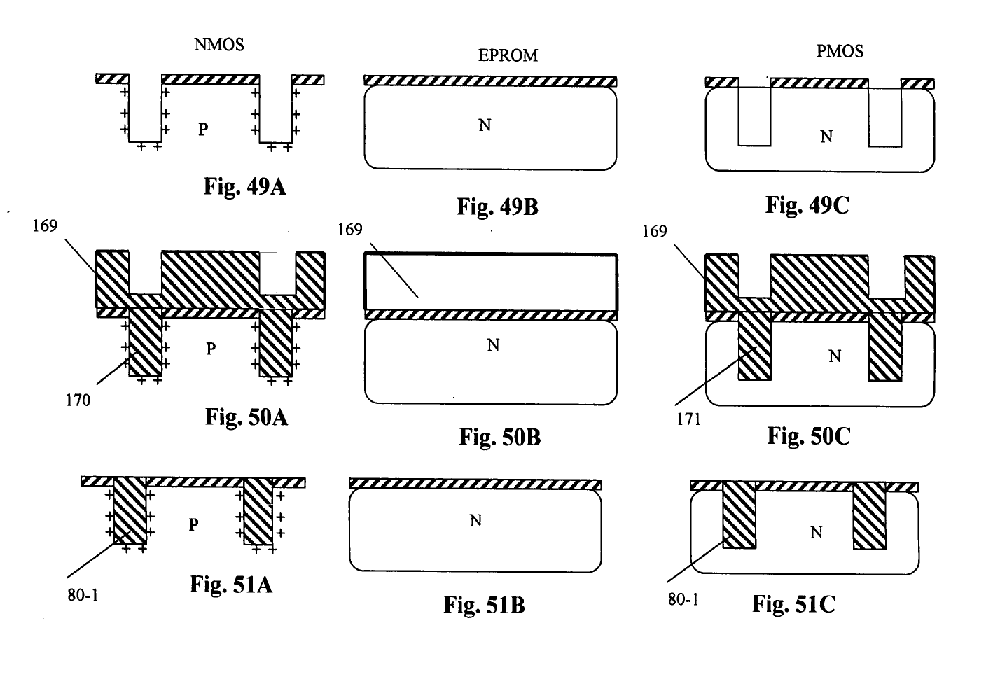

Next, the photo resist is removed as shown in FIGS. 49A, B and C followed by deposition of CVD oxide 169 over the wafer as shown in FIGS. 50A, B and C to fill the trenches 170, 171 of the NMOS and PMOS devices and the trenches not shown in FIGS. 46B-51B adjacent the positions where the EPROM cell recessed gate windows will be formed. In alternative embodiments, instead of angled implant and deposition of CVD oxide, these two steps can be replaced with a single deposition of boron doped CVD oxide into the deep field oxide trenches described herein.

Using chemical and mechanical polishing techniques, the wafer is polished till the CVD oxide in the field oxide trenches is at the same level as nitride 68 as shown in FIGS. 51A, B and C. All the processing from this point forward to completion of the vertically oriented EPROM is as previously described in FIG. 12 through FIG. 34.

An Enlarged view of one of the EPROM cells constructed with the process just described is shown in FIGS. 42 and 43.

Another embodiment of this invention is shown in FIGS. 52A, B, C and D. The embodiment of FIGS. 52A, B, C and D still has the deep field oxide on two sides of each recess (or enough of the perimeter to increase the coupling ratio to sufficiently high levels as feature sizes get smaller), but eliminates the third polysilicon layer needed for the bit line by substituting a buried bit line 5204 and also extending the drain implant 86 across the array to act as a second bit line. FIG. 52A is the top view of such an vertically oriented EPROM transistor cell. FIG. 52B is the section along AA′ of FIG. 52A. FIG. 52C is a section along BB′ of FIG. 52A.

To start forming this structure, a recess 5201 is formed in P silicon 82. The bottom of the recess has an oxide layer 5203. An N+ buried layer 5204, which will be a combined bit line and source, is formed by ion implant below oxide layer 5203. N+ layer 5204 is the source of the vertically oriented EPROM transistor as well the first bit-line that connects the sources of all the EPROM transistors in a column.

Recess 5201 has four side surfaces 164, 165, 166 and 167. The thin gate oxide 100 is formed on all four sides of the recess (or however many sides there are). Note that the thin gate insulating layer 100 is not shown in the top view of FIG. 52A but it is there. The same is true for the top views of FIGS. 42A and 54A.

Two sides 167, 165 form the active transistor having drain region N+ silicon 86 and channel region comprised of P silicon 82 with a layer of Oxide Nitride sandwich 5202 on top of the drain as best seen in FIGS. 52A and B. P silicon 82 is the substrate or body of the EPROM transistor, and will be converted to a channel region when voltage is applied to the control gate if said voltage is above the threshold voltage. The N+ layer 86 becomes the drain of an EPROM transistor as well as a second bit line that connects drains of all the EPROM cells in a column. The other two sides 164, 166 are bounded by field oxide 80-1 as in FIGS. 52A and C so as to reduce the amount of parasitic capacitance C1.

A floating gate poly layer 102 is formed inside the recess 5201 in the same manner as the previous embodiments. The 3 dimensional view of floating gate poly silicon is as shown in FIG. 52D. A layer ONO 104 is deposited followed by a layer of thick poly silicon 110. This layer 110 fills the recess to form the control gate 110-1 of EPROM as well as word line 110-2 connecting all the EPROM cells in a row. A layer of oxide 113-1 is formed on the top of poly layer 110-2 for insulation.

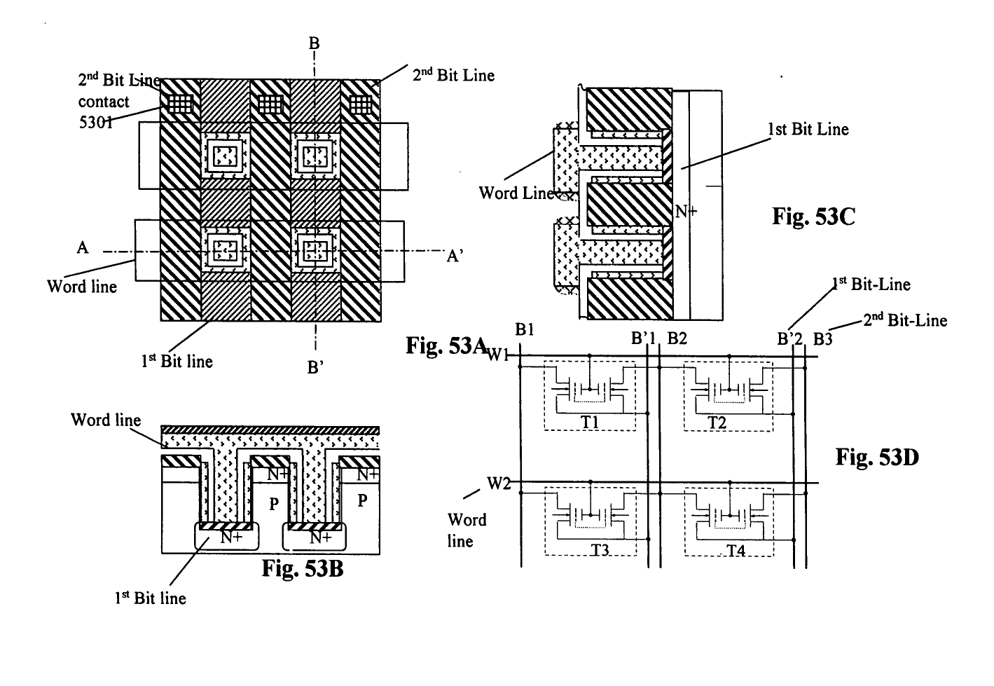

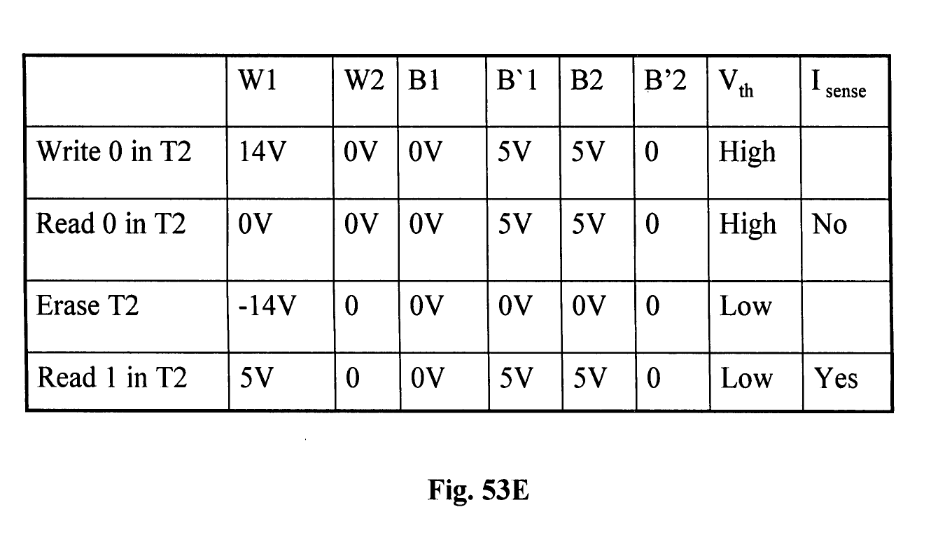

FIG. 53A shows a four transistor array of EPROM transistors of the type shown in FIG. 52A. FIG. 53B shows the section along AA′ of FIG. 53A. FIG. 53C shows the section along BB′ of FIG. 53A. The equivalent circuit of the array and the transistors is shown in FIG. 53D. The 2×2 array of transistors T1, T2, T3 and T4 are connected by word lines W1 and W2 and bit lines B1, B′1, B2, B′2 and B3. Having all these bit lines makes it easier to build the circuit and to operate it. The operation to Write, Read ‘0’ Erase and Read ‘1’ in the transistor n is shown in Table of FIG. 53E.

The main advantage of this embodiment is that the process to build this structure is simpler and easily manufacturable.

Another very exciting embodiment of this invention is shown in FIGS. 54A, B, C and D. The basic difference between the embodiment of FIG. 54A and FIG. 52A is that an additional mask is used to cut the floating gate poly tube into two pieces as shown in FIG. 54D so as to double the density by forming two separate active transistors in every recess. FIG. 54A is the top view of an EPROM transistor cell. FIG. 54B is the section along AA′ of FIG. 54A. FIG. 54. C is section along BB′ of FIG. 54A.

A recess 5401 is formed in P silicon 82. The bottom of the recess has an oxide layer 5203. A buried N+ layer 5204 is formed by ion implant below oxide layer 5203. N+ layer 5204 is the source of the EPROM transistor as well first bit-line that connects the sources of all the EPROM transistors in a column.

Recess 5201 has four side surfaces 164, 165, 166 and 167. The thin gate oxide 100 is formed on all four sides of the recess. Two sides 167, 165 form active vertically oriented MOS transistors because they are bounded by N+ silicon 86 to form a drain and P silicon 82 where a channel region will be formed if voltage above a threshold is applied to the control gate. Charge stored on the floating gate determines the threshold. A layer of Oxide Nitride sandwich 5202 is formed on top of the drain region as shown in FIGS. 54A and B. P silicon 82 is the substrate or body of the EPROM transistor. The N+ layer 86-1 becomes the drain of an EPROM transistor as well as a second bit line that connects drains of all the EPROM cells in a column. The other two sides 164, 166 are bounded by field oxide 80-1 as in FIGS. 54A and C so as to reduce the amount of parasitic capacitance C1.

A floating gate poly layer 102 is formed inside the recess 5201. Using a masking operation, the floating gate poly is separated in two parts 102-1 and 102-2 as shown in FIG. 54A and FIG. 54D. A layer ONO 104 is deposited followed by a layer of thick polysilicon 110. This poly layer 110 fills the recess to form a shared control gate 110-1 of the two EPROMs formed in each recess as well as shared word line 110-2 connecting all the EPROM cells in a row. A layer of oxide 113-1 is formed on the top of poly layer 110-2 for insulation. Two floating gates 102-1 and 102-2 in the same recess form two separate EPROM transistors with common source 5204, common control gate 110-1, separate drains 86-1 and 86-2 and separate floating gates 102-1 and 102-2. Hence now each recess has two EPROM transistors which can be separately programmed thereby doubling the density.

The 3 dimensional view of floating gate poly silicon is as in FIG. 54D.

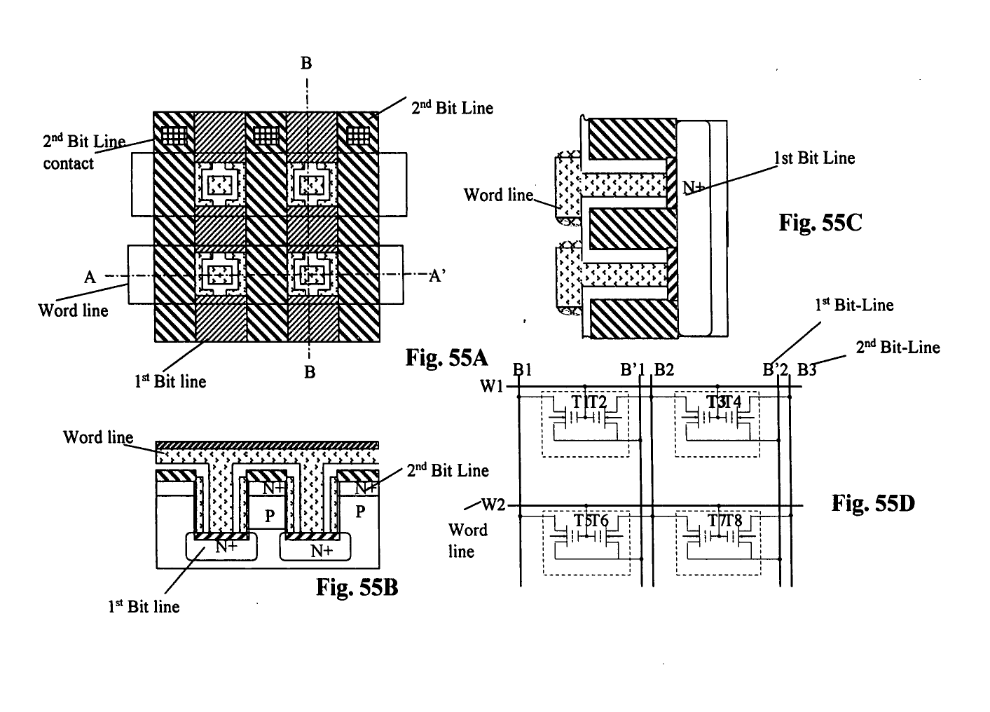

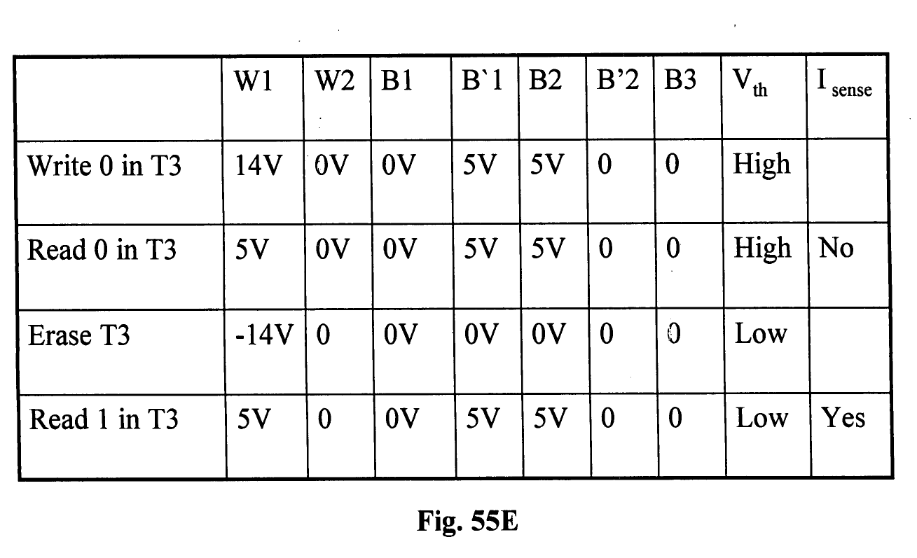

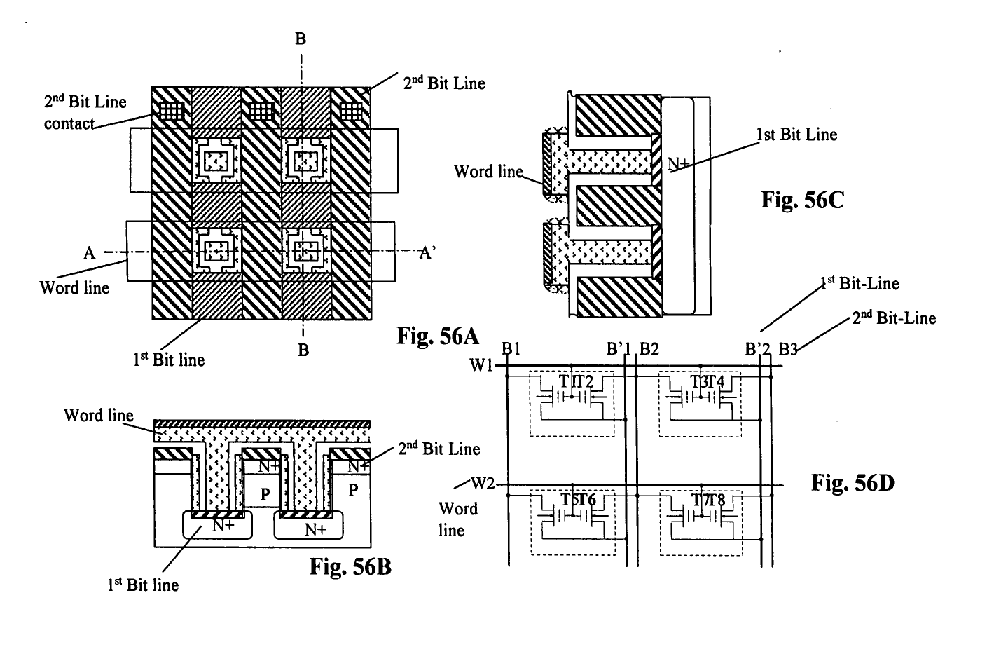

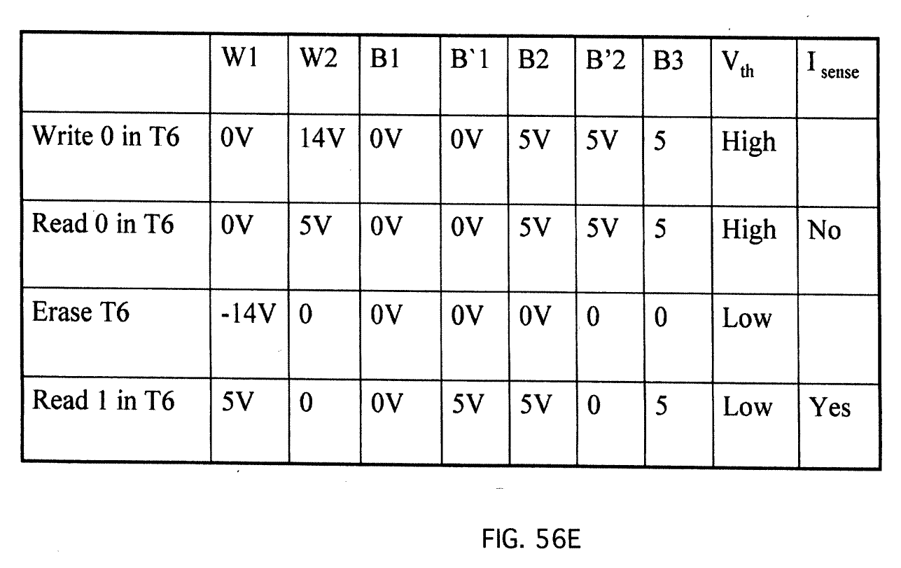

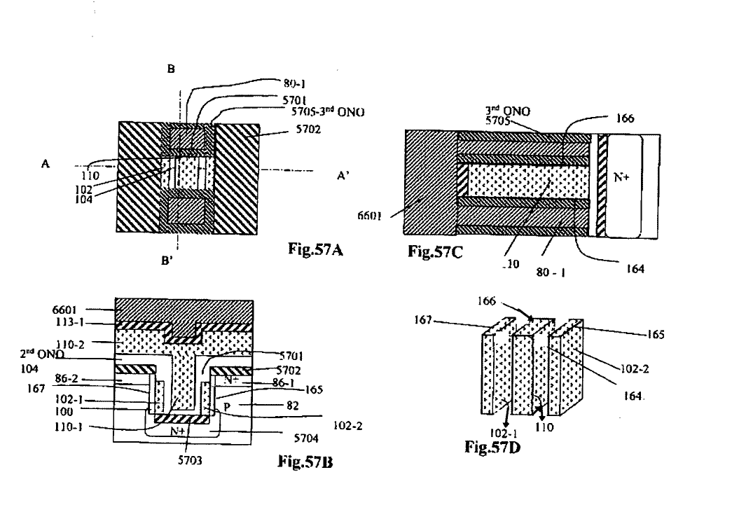

FIG. 55A shows a 4 transistor array of EPROM transistor of the type shown in FIG. 54A. FIG. 55B shows the section along AA′ of FIG. 55A. FIG. 55C shows the section along BB′ of FIG. 55A. The equivalent circuit of the array and the transistors is shown in FIG. 55D. The 4×2 array of transistors T1 through T8 are connected by word lines W1 and W2 and bit lines B1, B′1, B2, B′2 and B3. The operation to Write, Read ‘0’ Erase and Read ‘1’ in the transistor T2 is shown in Table of FIG. 55E. As another example of addressing transistors in this 4×2 array the operation to Write, Read ‘0’ Erase and Read ‘1’ in the transistor T6 is also shown in Table of FIG. 56E.

One method of constructing the structure of FIGS. 52A, B and C and FIGS. 53A, B and C using state of the art processing techniques is described here. On P type silicon an N+ layer 86 is implanted. This is followed by a deposition of an oxide and nitride layer. Then deep channels 5205, shown in FIG. 54A, are etched where field oxide 80-1 and the recess will be formed. N+ source implant 5204 is done in the channel. Then P type field implant is done at an angle to dope sidewalls followed by thick CVD oxide deposition and polishing using chemical and mechanical polishing technique. Now using a mask, etching CVD oxide from the channel forms a recess. From this point the processing steps are identical to the ones described in FIG. 15 through FIG. 27, however third poly deposition as shown in FIGS. 28 and 29 is not needed. The rest of the processing steps are the same as shown in FIGS. 30 and 31.

The main advantage of this embodiement is that the density of EPROM transistors has increased by a factor of two over the preferred embodiement while adding a masking step.

### Third Alternative Embodiment of Vertical Flash EPROM

Another embodiment of this invention is shown in FIGS. 57A, B, C and D. These figures represent the third alternative embodiment of the vertical flash EPROM cell. This embodiment has the improved coupling ratio (approximately 50% for all feature sizes) advantage from deeper field oxide, and has a cell area of 2F squared for all feature sizes.

FIG. 57A is the top view of an EPROM transistor cell. FIG. 57B is the section along AA′ of FIG. 57A. FIG. 57. C is section along BB′ of FIG. 57A. A recess 5701 is formed in P Silicon 82. The bottom of the recess has an oxide layer 5703. A buried N+ layer 5704 is formed by ion implantation below oxide layer 5703. N+ Layer 5204 is the source of the vertically oriented EPROM transistor and also functions as a first bit-line that connects the sources of all the vertical EPROM transistors in a column of an array.

Recess 5701 has four side surfaces 164, 165, 166 and 167 in the preferred embodiment, but any other number of sides (within reason) could also be formed or the recess could be round or oval, etc. Four sides will be assumed for the rest of this discussion. The thin gate oxide 100 is formed on all four sides of the recess. Two sides 167, 165 form separate active vertically oriented transistors because they are bounded by N+ silicon 86 and P silicon 82 and are also bounded by a portion of the source region 5704.

A layer of Oxide Nitride sandwich 5702 on top of the drain regions 86-1 and 86-2 is shown in FIGS. 57A and B. This ONO layer insulates the drain regions of the separate transistors to insulate the drain regions from the control gate and prevents the deep field oxide 80-1 in FIG. 57C from penetrating down the sides of the recess where it is desired to form an active transistor.

P Silicon 82 is the substrate or body of the EPROM transistor. The N+ layer 86-1 becomes the drain of a first vertically oriented EPROM transistor as well as a second bit line that connects drains of all the EPROM cells in a column.

The other two sides of the recess 164, 166 are bounded by field oxide 80-1 and 3rd ONO layer 5705 as shown in FIGS. 57A and C and do not form active transistors thereby reducing the value of C1 and maintaining a sufficiently high coupling ratio to have an adequately low programming voltage as feature sizes sizes get smaller.

Self aligned floating gate poly layers 102-1 and 102-2 are formed inside the recess 5701 as shown in FIG. 57A and FIG. 57D. All floating gates in the original vertical flash embodiment of FIGS. 1-34 and the first, second and third alternative embodiments thereof are self aligned thereby enabling major savings in cell size area by reducing design rule tolerances that would otherwise be necessary if masks and lithography were used to form these floating gate structures. The self alignment is achieved using an anisotropic etch which removes all horizontal components of the floating gate poly. This causes horizontal poly on the surface of the substrate beyond the perimeter of the recesses like reces 5701 and removes the poly from the bottom of the gate recess also. Therefore, the lateral extents of the self aligned floating gates are determined by the inherent characteristics of the anisotropic etch and not by the accuracy of photolithography.

A layer of ONO 104 is deposited into each recess to act as the insulating layer between the floating gate polysilicon and the control gate polysilicon. This is followed by deposition or growth of a layer of thick poly silicon 110 which will form the control gate and the word line. This layer 110 is photolithographically etched away to form the control gate 110-1 of each EPROM in a row of the array as well as the Word line 110-2 connecting all the control gates of all the EPROM cells in said row.

A layer of Oxide 113-1 is formed on top of poly layer 110-2 to insulate it from other conductive connections not relevant to the invention which are needed for the NMOS and PMOS transistors that are typically formed outside the EPROM cell array to do functions such as sense amps and other peripheral circuits.

Two floating gates 102-1 and 102-2 in the same recess form two separate EPROM transistors with common source 5704, common control gate 110-1, separate drains 86-1 and 86-2. Therefore each recess has two EPROM transistors formed in it, and density gains are achieved.

A three dimensional view of the twin floating gate poly silicon floating gates is shown in FIG. 57D.

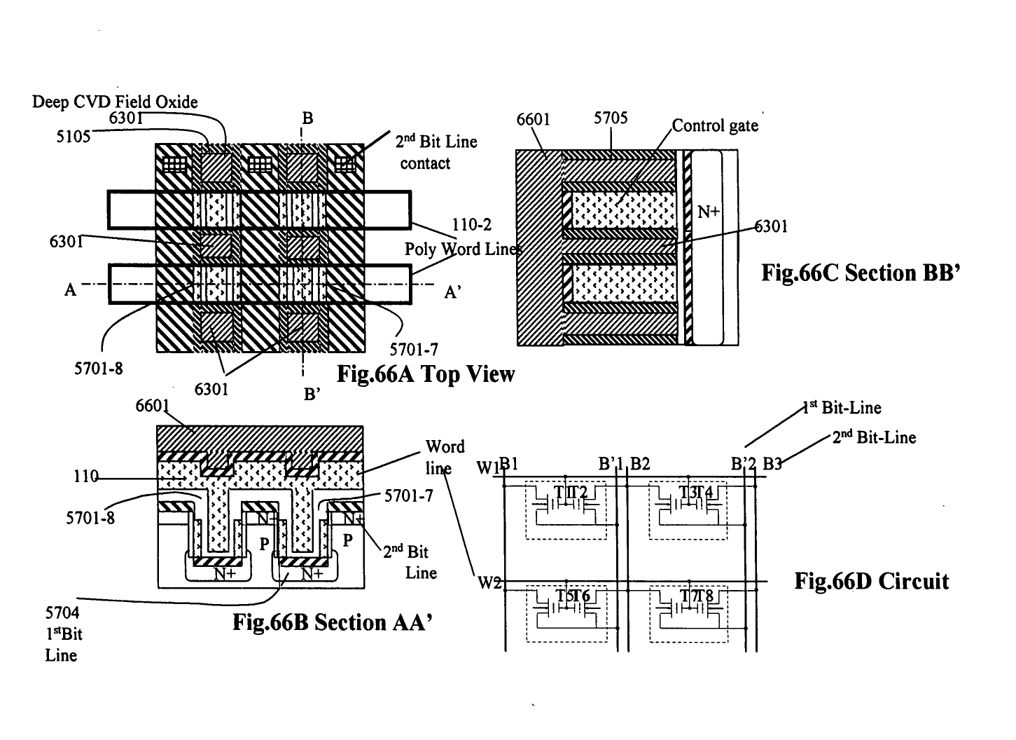

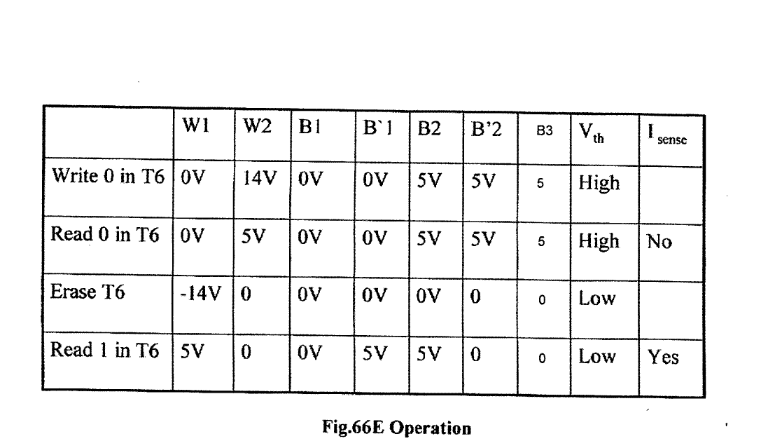

FIGS. 66A, B and C show a 2×2 array of EPROM cells of the structure shown in FIGS. 57A-57D. Each cell has two EPROM transistors. FIG. 66D shows an equivalent circuit schematic of the array of FIG. 66A and FIG. 66E shows a table describing the voltage conditions for operation of one cycle for programming, reading, erasing and reading again the T6 transistor in the EPROM array of FIG. 66A.

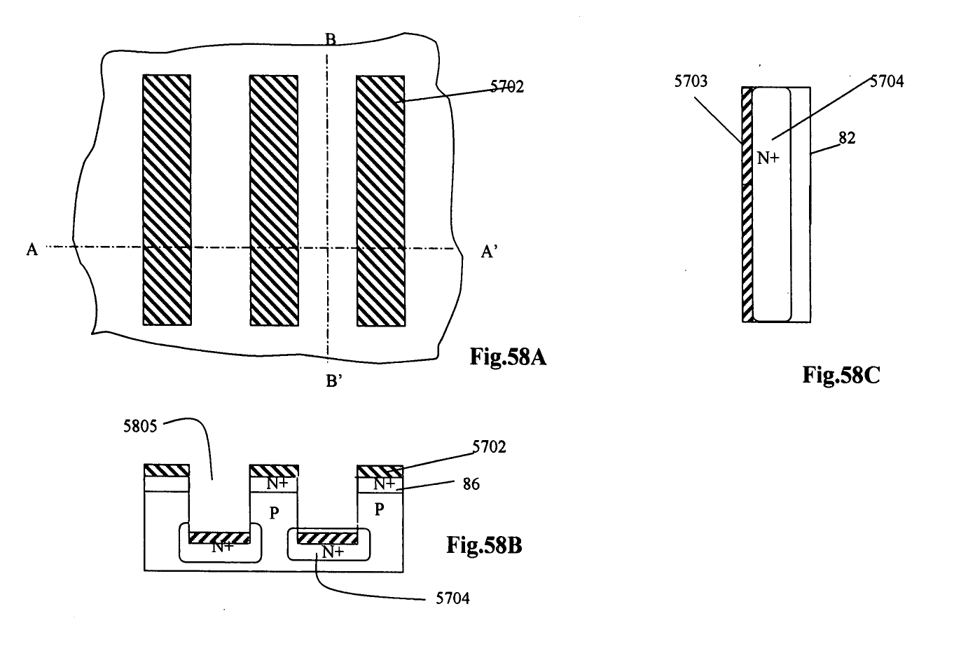

One method of constructing the array of 2×2 EPROM cells shown in FIG. 66A-66C and having the individual cell structure shown in FIGS. 57A, B and C is shown in FIGS. 58A through 65C. This method uses state of the art processing techniques. On P type silicon, an N+ layer 86 is implanted followed by a deposition of a first ONO (oxide and nitride) layer 5702. The N+ layer is the layer from which drain regions 86-1 and 86-2 in FIG. 57B will be formed. Then deep channels (also called trenches or recessed gate windows) 5805 are etched to form the recessed gate windows in which vertical EPROM cells will be formed. A layer of nitride (not shown) is deposited and etched anisotropically (etches nitride off horizontal surfaces only) so as to form a nitride insulation layer on the sidewalls only of the trenches. This nitride layer is not shown because it is only present while the bottom oxide layer 5703 is grown and then gets removed immediately thereafter.

An N+ source implant 5704 is done in the trenches to form the buried source and bit line followed by growth of thick thermal oxide 5703 on the bottoms of the trenches as shown in FIGS. 58A, B and C. Now the nitride layers on the sidewalls of the trenches are stripped as in FIG. 58B.

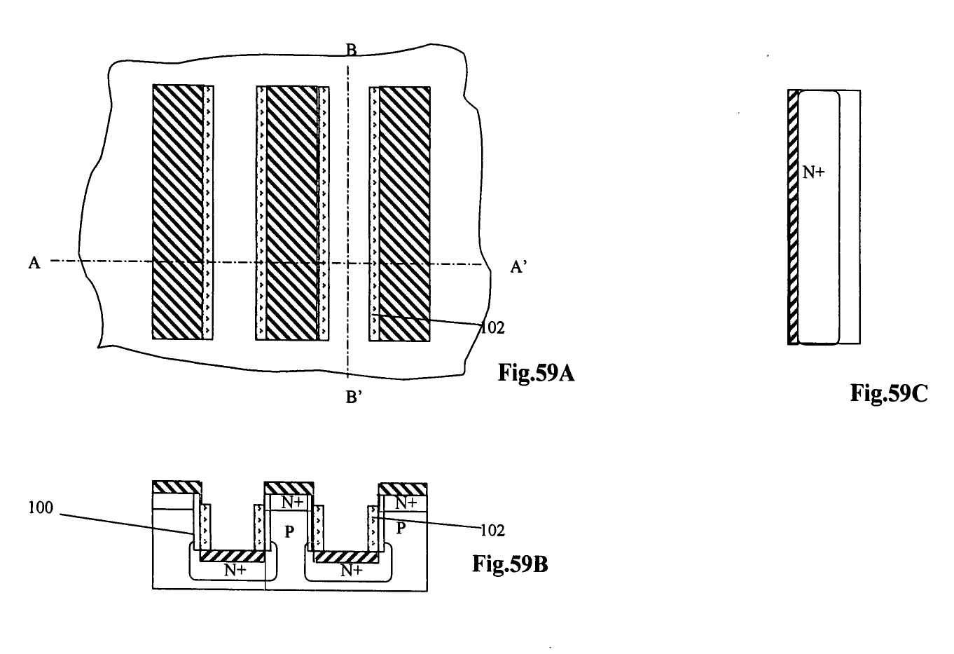

Next, a thin gate oxide 100 (FIG. 59B) is grown on the sidewalls of the trenches.

A layer of poly-silicon 102 is deposited next and etched anisotropically to remove the poly from the horizontal surfaces but not the vertical surfaces as in FIGS. 59A, B and C. This step is what causes the self aligned poly floating gates 102 in FIG. 57B to be formed and is the same step that is used in all the processes described herein to form all the self aligned poly floating gates used in all vertically oriented EPROM cells disclosed herein. The floating gates are self aligned because lithography is not needed to create them and this allows the cell to be made much smaller in area.

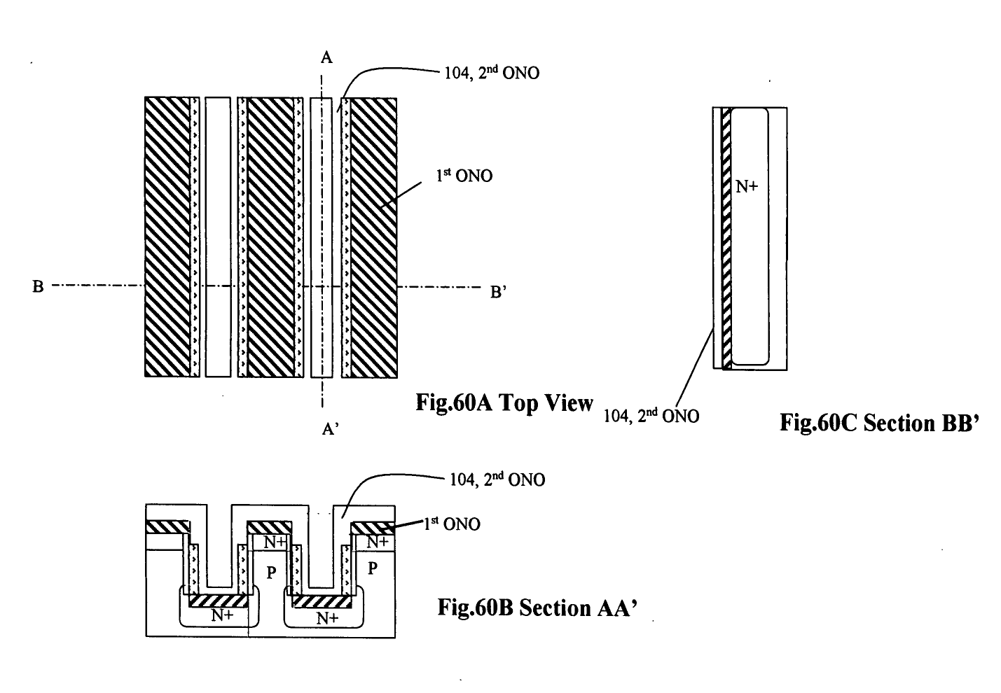

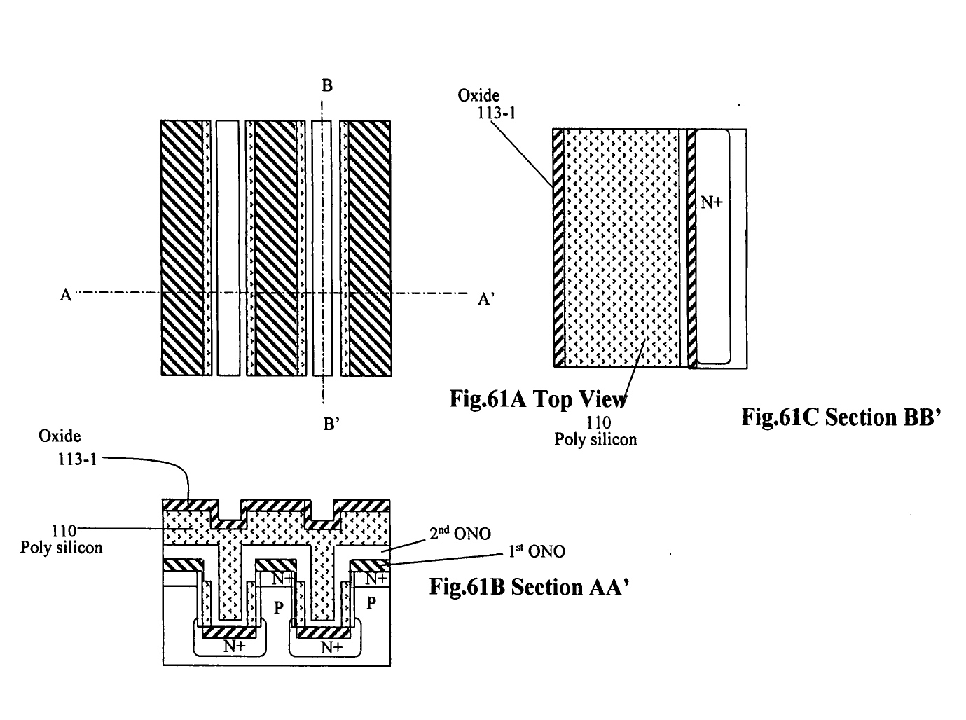

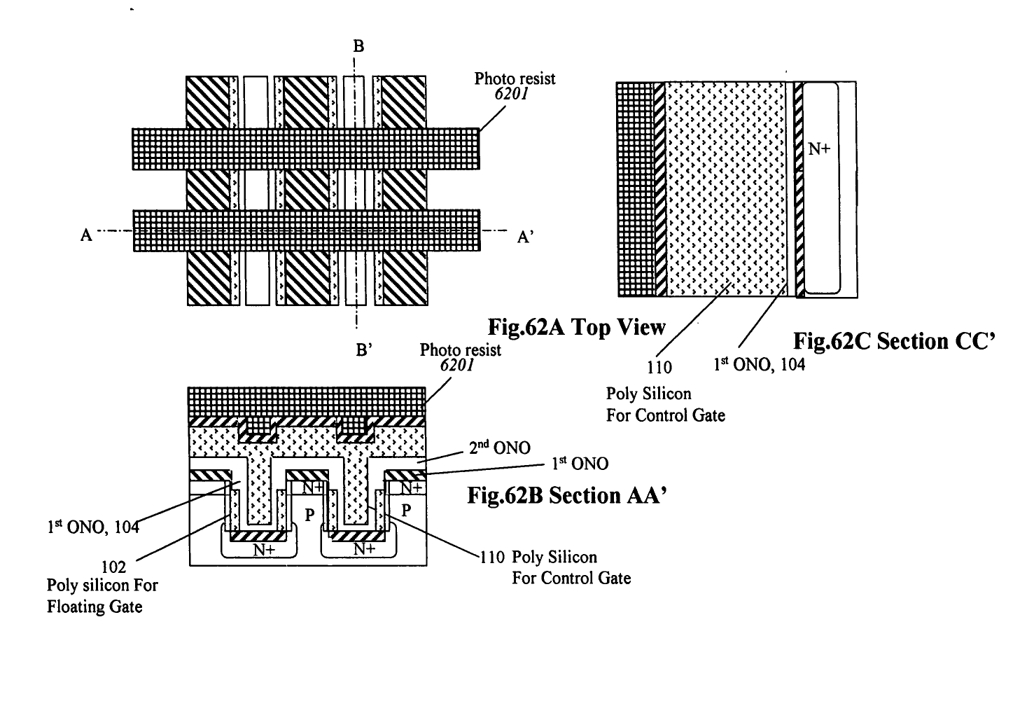

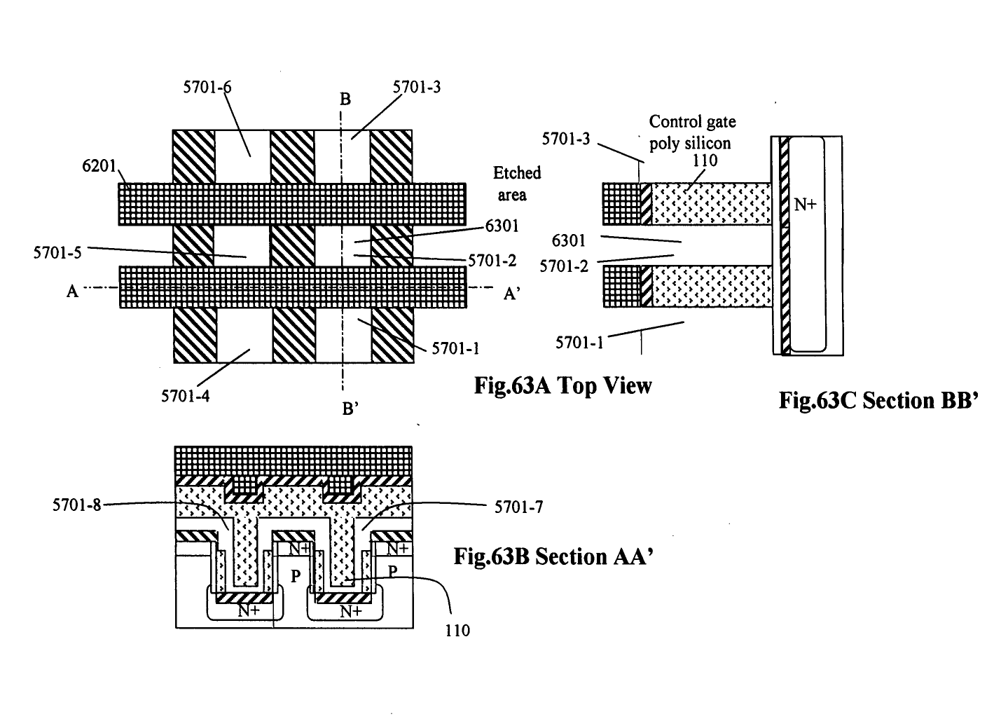

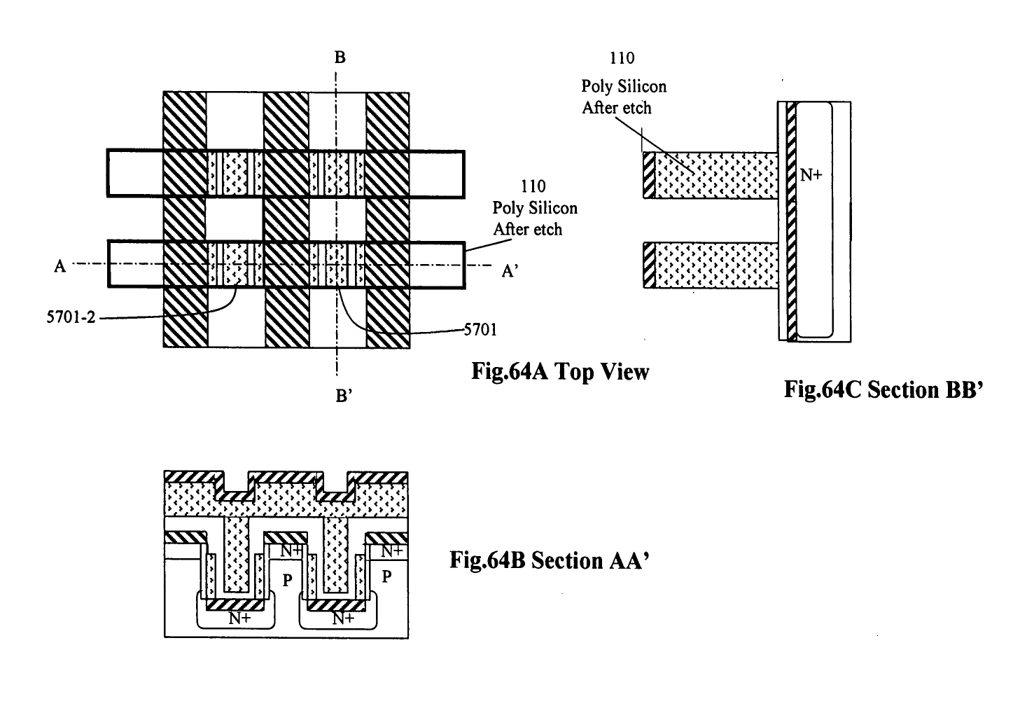

Then a 2nd ONO layer 104 is deposited as in FIGS. 60A, B and C. This layer will act as the intergate insulator that insulates the floating gate 102 from the control gate 110. Now a layer of poly-silicon 110 is deposited from which the control gate will be formed followed by a deposition of oxide layer 113-1 as shown in FIGS. 61A, B and C. This oxide layer 113 insulates the word line and control gate of each cell from the bit line that will be formed over it. Next a layer of photo-resist 6201 is deposited and developed as shown in FIGS. 62A, B and C to mask the floating gate poly 102, 2nd ONO 104 and control gate poly 110. Now using the defined photo-resist 6201, parts of the poly 102, 2^{nd} ONO 104 and poly 110 is removed from area 6301 (FIG. 63A) to form field oxide holes 5701-1 through 5701-6 as best seen in FIGS. 63A and 63C. Then photo-resist is stripped to expose the construction of the vertical, self-aligned floating gate EPROM in recess 5701-7 and 5701-8 as best seen in FIGS. 63B and 64A.

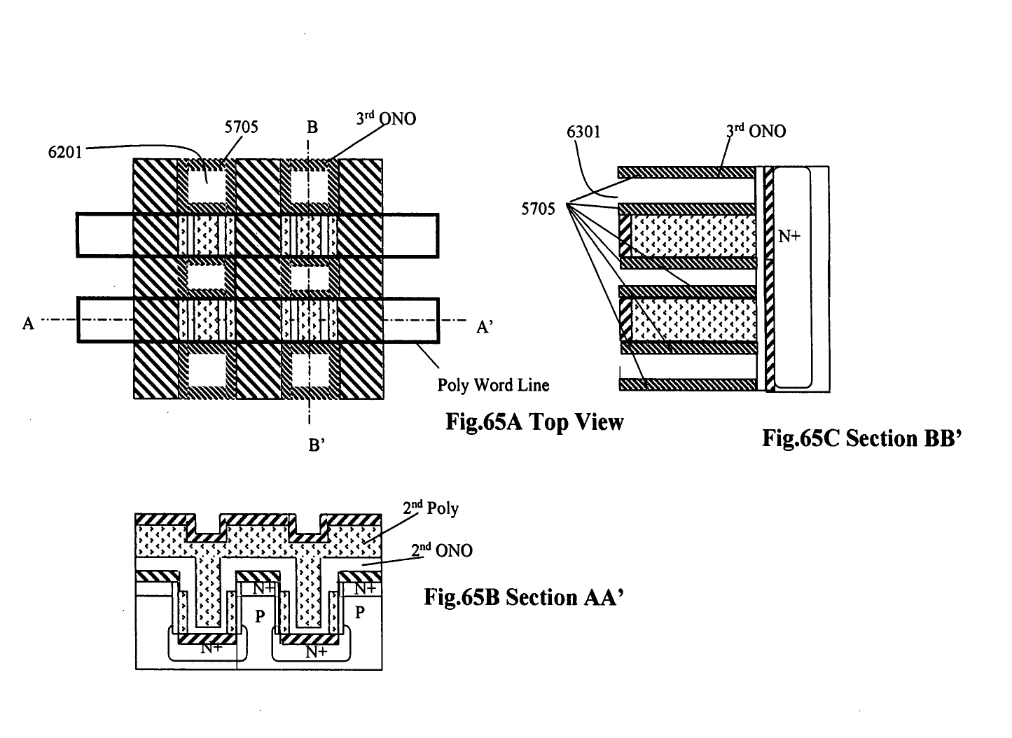

Now a 3rd ONO layer 5705 (see FIGS. 65A and C) is deposited in each of the field oxide holes and etched anisotropically to remove all the ONO on horizontal surfaces so as to leave the structure as shown in FIG. 65A and FIG. 65C with the ONO only on vertical surfaces of the field oxide holes adjacent the recessed gate windows as well as adjacent the NMOS and PMOS devices. Finally a thick layer of CVD field oxide 6301 is deposited in all the field oxide holes 5701-1 through 5701-6. This deposited field oxide fills the deep field oxide trenches that border two sides of each recessed gate window in which an active vertical EPROM device is formed thereby reducing the capacitance C1 and improving the coupling ratio. The CVD oxide is then planarized. The deep field oxide regions also isolate recessed gate windows 5701-1 and 5701-2 from each other, as shown in FIGS. 66A, B and C.

From this point the processing steps are identical to the ones described in FIG. 15 through FIG. 27 to make contact holes, metal lines and finish the CMOS process steps. However, the third poly deposition, as shown in FIGS. 28 and 29 to form bit lines over the top of the substrate is not needed because of the formation earlier in the process of buried bit lines 5704. The rest of the processing steps are the same as in FIGS. 30 and 31.

FIG. 66D shows the schematic of the array. Buried N+ source layer 5704 doubles at the 1^{st} bit-lines B′1 and B′2. The N+ drain layer 86 also forms the 2^{nd} bit-lines B1, B2 and B3. Poly layer 110 forms the control gates 110-1 as well as word lines W1 and W2. These word lines and bit-lines connect EPROM transistors T1 through T6 into an array. Any one of the transistors can be selected using these word-lines and bit-lines to write or read any one of the transistors in the array.

An example of addressing transistors in this 4×2 array the operation to Write, Read ‘0’ Erase and Read ‘1’ in the transistor T6 is shown in the of FIG. 66E.

The main advantage if this third alternative embodiment shown in FIGS. 66A, B and C is that the process of fabrication is simpler than the embodiment shown in FIGS. 54A, B and C. Density is higher than the embodiment of FIGS. 54A, B and C because there are separate and independent vertically oriented, self-aligned floating gate EPROM devices in each recessed gate window. The size of each EPROM cell in the array of FIGS. 66A, B and C is quantified by 2F² where F is the lithography feature size. For comparison, the cell in the alternative embodiment of FIGS. 54A, B and C had a size of 3F² and the cell in the alternative embodiment of FIGS. 52A, B and C has size of 4F². The parent embodiment shown in FIGS. 38, 39 and 40 also had a cell size of 4F² and it needed third poly for the bit lines and did not have the deep field oxide bounding some of the walls of each recessed gate window.

All these cell are connected in NOR configuration in the array as in FIG. 66D. For comparison of the cell sizes in the prior art to the cell sizes of the various embodiments of the invention disclosed herein, the cells in the state of the prior art arrays are about 12F² when connected in NOR configuration.

### Vertical NMOS Transistor Structure

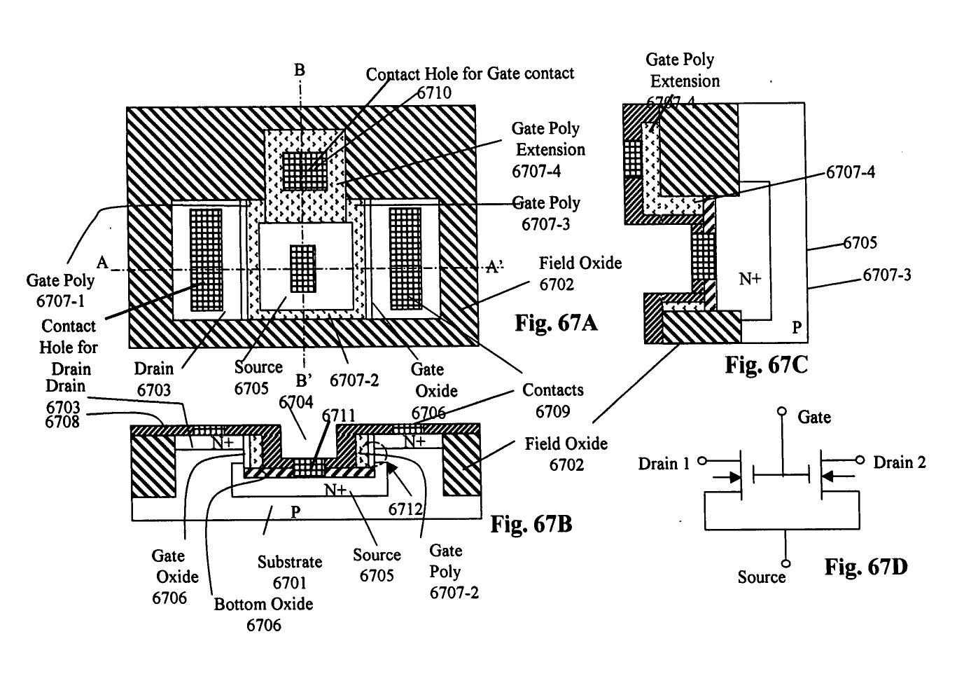

Another embodiment of this invention is a vertical n-MOS transistor with no floating gate, a shared source and gate and separate drains as shown in FIGS. 67A, B and C. FIG. 67A shows the top view. FIGS. 67B and 67C show the sections along AA′ and BB′ respectively. On substrate 6701 a field oxide 6702 formed to isolate n-MOS transistors. A N+ layer 6703 is formed and acts as a drain of the vertical n-MOS transistor. Separate drain contact holes 6709 shown in FIG. 67A make contact to the separate drain regions. The profile the N doping in the N+ Layer 6703 can be designed to meet the critical field requirement at the N/P junction to prevent degradation of the device from electric fields that are too high. After forming the N+ layer 6703, a vertical trench or recess 6704 is formed. The vertical n_MOS transistor will be formed in this trench. This is followed by creation of a N+ layer 6705 which will act as a common source. After forming the common source layer, a thermal oxide layer 6706 is at the bottom of the recess 6704 to insulate the source from the polysilicon gate contact and overlying metal layers that will enter the trench when contact lines are formed. Next, a thin gate oxide 6706 is grown on the semiconductor sidewalls of the trench followed by deposition and selective etching of N+ doped poly silicon to form the poly layer from which the gate contacts 6706-2 will be formed. There are 4 electrically interconnected regions of poly silicon 6707-1, 6707-2, 6707-3 and 6707-4. The idea is to form three vertical self-aligned polysilicon walls (6707-1, 6707-2, 6707-3) in the recess with no horizontal components on the top horizontal surface of the substrate or the horizontal bottom of the recess 6704. We also want one horizontal polysilicon component which is in electrical contact with the three vertical poly walls and has a contact hole (6710) to make contact with a metal line which will be the gate contact. The three vertical poly walls 6707-1, 6707-2, 6707-3 will be the gate contact. To form these three vertical poly walls 6707-1, 6707-2, 6707-3, a mask is placed over area 6707-4 to form a photoresist area to define the shape of poly area 6707-4. Then, to form the vertical polysilicon walls, an anisotropic etch is performed to remove all horizontal components of poly which are not protected. This leaves the polysilicon which forms the three self-aligned poly walls 6707-1, 6707-2, 6707-3 and contact region 6707-4. These three vertical poly walls are self-aligned because they do not have any horizontal component which would extend out of the well because of the way the anisotropic etch works. This allows the device to made much smaller and the length of the gate can be very small and precisely controlled as to its size. Small gates make for fast transistors. Precise control of the length of the gate means that distributions of operable devices with suitable operating speeds will be in a tight pattern.

Contact holes 6709, 6710 and 6711 are also formed so as to make contact with drain, gate and source regions, respectively.

Poly region 6707-2 and 6707-4, source region 6705 and Drain region 6703 form two transistors in parallel as shown in the equivalent circuit of FIG. 67D.

Poly silicon region 6707-2 is parasitic element and does not contribute to transistor functionality.

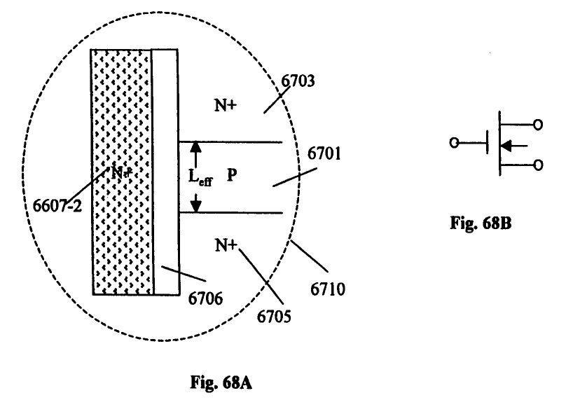

Region 6712 of FIG. 67B is enlarged in FIG. 68A to show the intrinsic n-MOS transistor and the length of the gate.

FIG. 68B shows an equivalent circuit schematic of an intrinsic, vertical, self-aligned, very small n-MOS transistor.

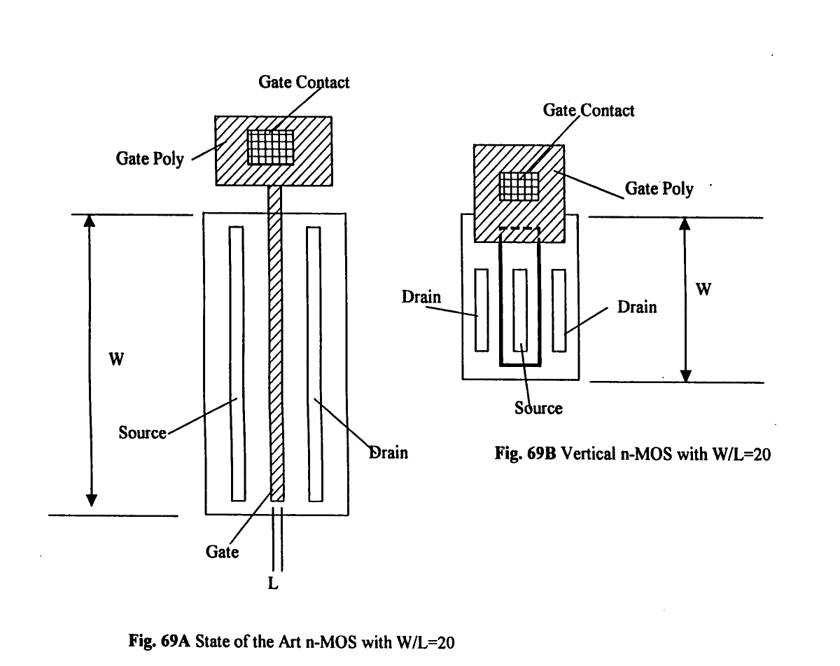

The main advantages of this n-MOS transistor over state of the art n-MOS transistor are,
1. The effective length or L_{eff}. of the channel, as shown in FIG. 68A, is independent of lithography, and therefore can be precisely controlled. The length of the gate region L_{eff}. can be precisely controlled because it depends only upon the characteristics of the N+ implant that forms the drain region 6703 and second N+ implant that forms the common source region 6705. These implant characteristics can be precisely electronically by controlling the implant energy and therefore controlling the depth of the implant. The implant depth control is on the order of 10 angstroms In contrast, prior art horizontal n_MOS transistors have their channel length L_{eff}. defined by the width of gate poly, which is in turn defined by lithography. Control of lithography is of the order of 25% of the feature size. Therefore, control of L_{eff}. is much less precise in the prior art. For example, for 100 nm feature size technology the value L_{eff}. would be plus/minus 25 nanometers too large or too small. The distributions of yield and performance will be much wider and economic losses will result.
2. The size of the vertical, self-aligned n-MOS device of the invention is smaller by a factor of 2 than prior art horizontal n-MOS transistor. This is illustrated in FIGS. 69A and B for the same W/L ratio of the transistor. W is the width of the transistor as in FIGS. 69A and B, and L is the length of the channel (L_{eff}.). L for the state of the prior art horizontal n-MOS transistor is shown in FIG. 69A. L for Vertical n-MOS transistor of the invention is shown in FIG. 68A but L is not labeled in this vertical transistor because it is a vertical dimension which goes down into the page.

### Another Advantage:

The charge retention time of flash memory, T_{R}, defines how long before the memory cell needs to be refreshed. If it is not refreshed, it will lose its data. Retention of data requires retention of trapped charges on the floating gate. There are two mechanism by which a floating loses the charge. First, involves the thickness of the gate oxide. The thinner the gate oxide, the faster is the loss of charge from the floating gate. Optimum floating gate oxide thickness is found to be 80 angstroms. The second mechanism for losing charge is that there are not enough electrons in the floating gate to start with. This is a function of the volume of the floating gate. The numbers of electrons trapped is dependent on the volume of the floating gate which, in horizontal prior art flash, depends upon its horizontal width and length the thickness of the gate poly. As MOS features become small, volume reduces dramatically, and charge retention times drop. For example, the volume of a standard Flash EPROM gate W×L×t, where W is the width, L is length of the gate and t is the thick ness of the gate. So with 90 nm features, the volumen of a Floating gate in a standard Flash EPROM is 90×90×10 or 81000 cubic nanometers.

In contrast, the structure presented in this invention can have much higher volume and much higher retention time. Although W and t is fixed, the length L of poly gate can be as long as the depth of the recess which can be 10 times more than the L possible in the prior art horizontal process with no area penalty for the size of each vertical, self-aligned EPROM cell. Hence T_{R} can be increased by a factor of 10 or more using the teachings of the invention.

### Another Embodiment

This invention is also applicable to other Flash EPROM structures such as MNOS devices or Si-nc memories. The teachings of the invention can be directly applied to these technologies by substituting composite oxide-nitride for the floating gate in MNOS devices. Similarly, for Si-nc memory cells, the floating gate poly is replaced with Si-nc material.

A p-MOS transistor can also be constructed by using appropriate dopings in the structure of FIGS. 67A,B and C.

One of the methods of the constructing the embodiment of FIGS. 67A,B and C is described below:

Regions of active areas on a P substrate 6701 are defined by forming field oxide regions 6702 that isolate the transistors. N+ implant is made in active areas except in the regions where P+ tap to substrate is made using photolithography. These N+ regions will form drains of n-MOS transistors. A recess 6704 is etched in the active area anisotropically. Then following the process shown in FIG. 15 through FIG. 19 described earlier, N+ source layer 6705 and bottom oxide 6706 are formed and gate oxide on the sidewalls is grown. Then a layer of poly is deposited followed by photo resist layer development to define region 6707-4. Four regions of gate poly are left (6707-1, 6707-2, 6707-3 and 6707-4) after poly is etched anisotropically. Region 6707-1 and 6707-3 are along the active sidewall and form active gates. Region 6707-2 is parasitic element. Region 6707-4 is used to connect active gate poly to contact area 6710. Next step is to deposit oxide and open contact holes. Final steps are to deposit and define the metal lines.

Although the invention has been disclosed in terms of the preferred and alternative embodiments described herein, those skilled in the art will appreciate different variations and alternatives which may be used to embody the teachings of the invention. All such variations and alternatives are intended to be included within the scope of the claims appended hereto.

1. (canceled)

2. (canceled)

3. (canceled)

4. (canceled)

5. A process for forming a vertically oriented EPROM cell comprising steps of:
using ion implants to dope source and drain regions in a substrate doped to the desired conductivity of a body region of a vertically oriented EPROM cell and controlling the implant energy of said ion implants to establish a desired gate length for a body region in said substrate between said source and drain regions;
forming a recess in said substrate deep enough to penetrate at least partially into said source region;
forming a gate insulator layer on the walls of said recess and an insulation layer on the bottom of said recess;
depositing a floating gate material in said recess and using an anisotropic etch to etch away horizontal components of said floating gate material to leave a self-aligned floating gate which does not extend laterally beyond a perimeter of said recess;
forming a control gate over and insulated from said floating gate and a word line in contact with said control gate; and
forming a bit line in contact with said drain region.

6. The process of claim 5 further comprising the step of forming deep field oxide regions bordering at least some of the walls of said recess and extending down into said substrate far enough to reduce a capacitance of a capacitor C1 sufficiently to obtain a desired coupling ratio regardless of feature size, where C1 is the capacitance between floating gate and said body region of said substrate.

7. (canceled)

8. A process for forming a vertically oriented n-MOS transistor comprising steps of:
using ion implants to dope source and drain regions in a substrate doped to the desired conductivity of a body region of a vertically oriented n-MOS transistor and controlling the implant energy of said ion implants to establish a desired gate length for a body region in said substrate between said source and drain regions;
forming a recess in said substrate deep enough to penetrate at least partially into said source region;
forming a gate insulator layer on the walls of said recess and an insulation layer on the bottom of said recess;
depositing a conductive gate material in said recess and using an anisotropic etch to etch away horizontal components of said gate material to leave a self-aligned gate which does not extend laterally beyond a perimeter of said recess;
forming a conductive paths to said gate and said source and drain regions.

9. (canceled)

10. (canceled)

11. (canceled)

12. A process for forming a recessed gate window for a vertically oriented EPROM cell in a semiconductor substrate so as to substantially improve the coupling ratio as feature sizes are reduced by reducing the capacitance C1 between a floating gate and a doped region of a semiconductor substrate forming the body of a vertically oriented EPROM cell and through which a conductive channel is selectively formed, said process comprising:
forming trenches in a doped semiconductor substrate so as to border a predetermined part of the perimeter of an area where a recessed gate window will be formed said trenches being deep enough to exceed the depth of a recessed gate window to be formed later;
doing an angled implant of impurities of a predetermined conductivity type so as to implant impurities into the walls and bottom of said trenches;
depositing CVD oxide in said trenches to form deep field oxide structures; and
forming said recessed gate window so as to border said trenches.

13. The process of claim 12 wherein said recessed gate window has four sides, and said trenches are formed so as to border two of said four sides.

14. A process for forming a recessed gate window for a vertically oriented EPROM cell in a semiconductor substrate so as to substantially improve the coupling ratio as feature sizes are reduced by reducing the capacitance C1 between a floating gate and a doped region of a semiconductor substrate forming the body of a vertically oriented EPROM cell and through which a conductive channel is selectively formed, said process comprising:
forming trenches in a doped semiconductor substrate so as to border part of the perimeter of an area where a recessed gate window will be formed said trenches being deep enough to exceed the depth of a recessed gate window to be formed later;
depositing boron doped CVD oxide in said trenches to form deep field oxide structures; and
forming said recessed gate window so as to border said trenches.

15. The process of claim 14 wherein said recessed gate window has four sides, and said trenches are formed so as to border two of said four sides.

16. A vertically oriented EPROM cell comprising:
a semiconductor substrate having a vertical trench formed therein;
means for forming a vertically oriented EPROM cell in said vertical trench with at least one self aligned floating gate in each said vertical trench and a control gate and a bit line and a word line;
means for causing a coupling ratio of said vertically oriented EPROM cell to remain high enough as feature sizes are scaled down to allow effective programming voltages to be used which are small enough to not cause damage by punchthrough.

17. (canceled)

18. (canceled)

19. A pair of vertically oriented EPROM memory cells formed in the same recessed gate window formed in a substrate, comprising:
a semiconductor substrate having formed therein a first layer doped with an impurity so as to have a first conductivity type such as P type and so as to act as the body of a vertically oriented EPROM cell through which a conductive channel region will be formed under predetermined conditions of stored charge and applied voltage, and having formed therein two separate second layers each of which is doped with an impurity so as to have a second conductivity type such as N type and adjacent to said first layer and electrically insulated from each other so as to act as separate drains of two separate vertically oriented EPROM cells to be formed in a recess in said substrate;
and wherein said recess is formed in said semiconductor substrate so as to penetrate down through said second and first layers, said recess having a circumference;
a field oxide layer formed so as to bound at least enough of said circumference of said recess so as to cause a coupling ratio to remain high enough as feature sizes of said vertically oriented EPROM cell are scaled downward in size to allow programming voltages to be used which are low enough to not cause punch through;
an insulating layer formed on a bottom of said recess;
an area of said substrate beneath said insulating layer formed on said bottom of said recess which has been doped to said conductivity type so as to act as a source for said vertically oriented EPROM transistor;
a gate insulating layer formed so as to cover at least part of the inside surface of said recess;
a pair of floating gates formed on top of said gate insulating layer and insulated from each other and formed at least at locations of said gate insulating layer which are in contact with said first and second layers in said substrate as opposed to portions of said gate insulating layer which are in contact with said field oxide;
a control gate formed in said recess and having a conductive portion which extends to make electrical contact with control gates of other EPROM cells in a row of said array so as to act as a word line; and
an insulating material insulating said control gate from said floating gate;
and wherein said recess walls are covered by said gate insulating layer and wherein said floating gate covers all said gate insulating layer but is split into two halves which are insulated from each other by an insulating layer.

20. A pair of vertically oriented EPROM memory cells formed in the same recess in a substrate, comprising:
a semiconductor substrate doped to a conductivity desired for the body of a vertically oriented EPROM cell;
a source and a pair of separate drain regions formed in said substrate by ion implants with the energy of said ion implants and not photolithography determining the effective gate length of the vertically oriented EPROM cell by determining the distance between the source and drain regions, each area in said substrate between said source and each of said separate drain regions being referred to herein as a body region;
a recess formed down into said substrate so as to penetrate at least partially into said source region, said recess having a perimeter;
deep field oxide bounding at least some portions of said perimeter of said recess and extending deep enough into said substrate at the portions of said recess which are bounded by said deep field oxide so as to decrease the value of a capacitance C1 between floating gates to be formed in said recess and said semiconductor substrate;
a gate insulator formed on walls of said recess and an insulation layer on the bottom of said recess, said source region being part of a doped area formed by ion implantation below said insulation layer formed on said bottom of said recess and forming a buried first bit line shared by a pair of vertically oriented EPROM memory cells to be formed in said recess;
a pair of self-aligned floating gates, each formed on at least a portion of said gate insulator so as to overlie a said body region, said self-aligned floating gates each having lateral extents beyond a perimeter of said recess which are determined by the inherent characteristics of an anisotropic etch used to form said self-aligned floating gate and not by photolithography;
a conductive control gate formed between said self aligned floating gates and insulated therefrom;
means for forming a word line in electrical contact with said control gate; and
means for forming a second bit lines in electrical contact with each of said separate drain regions.

21. A vertically oriented MOS transistor, comprising:
a semiconductor substrate doped to a conductivity desired for the body of a vertically oriented MOS transistor;
a source and drain region formed in said substrate by ion implants with the energy of said ion implants and not photolithography determining the effective gate length of the vertically oriented MOS transistor by determining the distance between the source and drain regios, each area in said substrate between said source and said drain region being referred to herein as a body region;
a recess formed down into said substrate so as to penetrate at least partially into said source region, said recess having a perimeter;
a gate insulator formed on walls of said recess and an insulation layer covering at least a portion of a bottom surface of said recess, said source region being part of a doped area formed by ion implantation below said insulation layer formed on said bottom of said recess;
a conductive gate formed over said gate insulator and positioned such that a predetermined voltage applied to said conductive gate will form a conductive channel through said body region between said source and drain regions;
means for forming an electrical contact to said gate;
means for forming an electrical contact to said source region; and
means for forming an electrical contact with said drain region.

22. A nonvolatile memory cell comprising:
a semiconductor substrate;
a vertical MOS transistor formed by alternating N-type and P-type doped layers in said substrate intersecting a well etched into said substrate so as to form a source and drain regions separated by a body region, said well having a gate of conductive material formed therein and insulated from said alternating N-type and P-type materials by a layer of gate insulating material and overlying said body region;
a contact comprising a layer of conductive material formed on said substrate so as to extend down into said well and make contact with said gate; and
means for making electrical contact with said source and drain regions.

23. The apparatus of claim 16 or 19 wherein said floating gate is comprised of composite silicon dioxide and silicon nitride to form an MNOS EPROM device.
